(19) United States
(12) Patent Application Publication
(10) Pub. No.: US 2026/0103823 A1
(43) Pub. Date: Apr. 16, 2026

(54) GALLIUM ARSENIDE SINGLE CRYSTAL SUBSTRATE AND METHOD OF PRODUCING SAME

(71) Applicant: SUMITOMO ELECTRIC INDUSTRIES, LTD., Osaka (JP)

(72) Inventors: Fuminori MITSUHASHI, Osaka (JP); Masahiro ADACHI, Osaka (JP); Yoshihiro SAITO, Osaka (JP); Yojiro NAKAYAMA, Osaka (JP)

(73) Assignee: SUMITOMO ELECTRIC INDUSTRIES, LTD., Osaka (JP)

(21) Appl. No.: 19/114,003

(22) PCT Filed: Apr. 17, 2023
(86) PCT No.: PCT/JP2023/015310

§ 371 Date: Mar. 21, 2025

(51) Int. Cl. C30B 29/42; C30B 33/02; C30B 33/10

(52) U.S. Cl. CPC C30B 29/42; C30B 33/02; C30B 33/10

(57) ABSTRACT

A gallium arsenide single crystal substrate has a main surface having a circular shape, and has a first integrated intensity ratio, a second integrated intensity ratio, a third integrated intensity ratio, a fourth integrated intensity ratio, and a fifth integrated intensity ratio, wherein the second integrated intensity ratio is 0.9 or more and 1.05 or less, each of the third integrated intensity ratio and the fourth integrated intensity ratio is 1.0 or less, the fifth integrated intensity ratio is 0.8 or less, and a ratio of the first integrated intensity ratio to the second integrated intensity ratio is 0.5 or more and 1 or less.

### TECHNICAL FIELD

The present disclosure relates to a gallium arsenide single crystal substrate and a method of producing the same.

### BACKGROUND ART

Japanese Patent Laying-Open No. 06-045318 (PTL 1) proposes a gallium arsenide single crystal substrate (hereinafter, also referred to as a “GaAs single crystal substrate”) with which thermal cleaning, which is an operation of removing an oxide film, can be performed at a low temperature in a short time. Such a GaAs single crystal substrate can be realized in such a manner that an interface transition layer rich in As and having a thickness of 3 Å or less is artificially formed at a surface thereof. Japanese Patent Laying-Open No. 2008-300747 (PTL 2) proposes to provide a GaAs wafer, which is made clean by at least cleaning a surface of a GaAs single crystal substrate with heat to such an extent that impurity and oxide at its surface can be removed by the thermal cleaning.

### CITATION LIST

### Patent Literature

PTL 1: Japanese Patent Laying-Open No. 06-045318
PTL 2: Japanese Patent Laying-Open No. 2008-300747

### SUMMARY OF INVENTION

A gallium arsenide single crystal substrate according to the present disclosure is a gallium arsenide single crystal substrate having a main surface having a circular shape. The gallium arsenide single crystal substrate has a first integrated intensity ratio, a second integrated intensity ratio, a third integrated intensity ratio, a fourth integrated intensity ratio, and a fifth integrated intensity ratio. Each of the first integrated intensity ratio and the third integrated intensity ratio is obtained by determining each of spectra of detection intensities of 3d electrons of gallium and arsenic with respect to binding energy of a photoelectron emitted to outside of the gallium arsenide single crystal substrate based on X-ray photoelectron spectroscopy in which X-ray is applied to a center of the main surface under conditions of an X-ray incident energy of 600 eV and a photoelectron take-off angle of 30°. Each of the second integrated intensity ratio and the fifth integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to the center of the main surface under conditions of an X-ray incident energy of 600 eV and a photoelectron take-off angle of 85°. The fourth integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to the center of the main surface under conditions of an X-ray incident energy of 600 eV and a photoelectron take-off angle of 45°. Each of the first integrated intensity ratio and the second integrated intensity ratio is a ratio of a sum of an integrated intensity of an arsenic element present as diarsenic pentoxide, an integrated intensity of an arsenic element present as diarsenic trioxide, an integrated intensity of an arsenic element present as gallium arsenide, and an integrated intensity of an arsenic element present as a metal arsenic to a sum of an integrated intensity of a gallium element present as digallium monoxide, an integrated intensity of a gallium element present as digallium trioxide, and an integrated intensity of a gallium element present as the gallium arsenide. Each of the third integrated intensity ratio, the fourth integrated intensity ratio, and the fifth integrated intensity ratio is a ratio of a sum of an integrated intensity of the arsenic element present as the diarsenic pentoxide and an integrated intensity of the arsenic element present as the diarsenic trioxide to a sum of an integrated intensity of the gallium element present as the digallium monoxide and an integrated intensity of the gallium element present as the digallium trioxide. The second integrated intensity ratio is 0.9 or more and 1.05 or less. Each of the third integrated intensity ratio and the fourth integrated intensity ratio is 1.0 or less. The fifth integrated intensity ratio is 0.8 or less. A ratio of the first integrated intensity ratio to the second integrated intensity ratio is 0.5 or more and 1 or less.

A method of producing a gallium arsenide single crystal substrate according to the present disclosure is a method of producing a gallium arsenide single crystal substrate having a main surface having a circular shape. The method includes: preparing a gallium arsenide single crystal substrate precursor having a surface having a circular shape; and obtaining the gallium arsenide single crystal substrate from the gallium arsenide single crystal substrate precursor. The obtaining includes: forming the surface of the gallium arsenide single crystal substrate precursor into a polished surface by polishing the surface; forming the polished surface into an alkali-cleaned surface by cleaning the polished surface with a first alkali cleaning liquid; forming the alkali-cleaned surface into an acid-cleaned surface by cleaning the alkali-cleaned surface with an acid cleaning liquid including 0.3 mass ppm or more and 0.5 mass % or less of an acid; forming the acid-cleaned surface into a second alkali-cleaned surface by cleaning the acid-cleaned surface by supplying a second alkali cleaning liquid to the acid-cleaned surface at a flow rate of 0.1 L/minute or more and 5 L/minute or less for 30 seconds or more and 5 minutes or less while rotating the acid-cleaned surface at a rotation speed of 1000 rpm or more in a peripheral direction; and forming the second alkali-cleaned surface into the main surface by performing heat treatment onto the second alkali-cleaned surface in an inert gas atmosphere under conditions of 1.1 atmospheric pressures or more and 3 atmospheric pressures or less and 150° C. or more and 300° C. or less. The first alkali cleaning liquid includes 0.1 mass % or more and 10 mass % or less of a first base. The first base at least includes one of a quaternary ammonium hydroxide and a quaternary pyridinium hydroxide. The second alkali cleaning liquid includes 0.3 mass ppm or more and 0.5 mass % or less of a second base. The second base at least includes one of the quaternary ammonium hydroxide and the quaternary pyridinium hydroxide.

### BRIEF DESCRIPTION OF DRAWINGS

FIG. 1 is an exemplary graph showing a relation between a measurement depth (horizontal axis) from a main surface of a GaAs single crystal substrate according to the present embodiment and each of a ratio (vertical axis) of an integrated intensity of the total of an arsenic element to an integrated intensity of the total of a gallium element and a ratio (vertical axis) of an integrated intensity of an arsenic element present as an arsenic oxide to an integrated intensity of a gallium element present as a gallium oxide.

FIG. 2 is an explanatory diagram schematically illustrating a configuration of an analysis system using X-ray photoelectron spectroscopy (XPS).

FIG. 3A is a graph showing an exemplary Ga3d spectrum after background correction as obtained based on XPS in which X-ray is applied to the center of the main surface of the GaAs single crystal substrate according to the present embodiment.

FIG. 3B is a graph showing an exemplary As3d spectrum after background correction as obtained based on XPS in which X-ray is applied to the center of the main surface of the GaAs single crystal substrate according to the present embodiment.

FIG. 4 is an explanatory diagram illustrating five measurement points set on a GaAs single crystal substrate having a diameter of 75 mm or more and less than 150 mm in the present embodiment.

FIG. 5 is an explanatory diagram illustrating nine measurement points set on a GaAs single crystal substrate having a diameter of 150 mm or more and 205 mm or less in the present embodiment.

FIG. 6 is a flowchart showing a method of producing the GaAs single crystal substrate according to the present embodiment.

### DETAILED DESCRIPTION

### Problem to be Solved by the Present Disclosure

As one of methods of evaluating a mirror surface property (i.e., presence or absence of a level difference) of a surface of an epitaxial film, haze is used, and it has been known that an increase in value of the haze is correlated with a decrease in device property. The haze refers to an amount of scattered light scattered due to an irregularity of the surface and fine defect and foreign matter present at the surface when laser light is applied to the surface of the epitaxial film. The haze is expressed as a ratio of the amount of scattered light to an amount of laser light incident on the surface. The haze is expressed based on parts per million (ppm) as a unit. It is evaluated that as the value of the haze is smaller, the surface has a higher mirror surface property and the level difference is smaller. The level difference results from a stacking fault generated when an epitaxial film is grown on the GaAs single crystal substrate, for example. Since the stacking fault depends on the mirror surface property of the main surface of the GaAs single crystal substrate, it is required to realize a GaAs single crystal substrate having a main surface having a high mirror surface property so as to reduce the value of the haze.

As means for realizing such a GaAs single crystal substrate having the main surface having the high mirror surface property by removing an oxide film in the main surface, wet etching has been known in addition to the thermal cleaning described above. The wet etching is means for removing the oxide film in the main surface by using a sulfuric-acid-based aqueous solution including sulfuric acid and hydrogen peroxide or by using a NH₄OH-based aqueous solution including ammonium hydroxide and hydrogen peroxide. However, due to poor wettability, the oxide film may not be sufficiently removed by the wet etching. In this case, the GaAs single crystal substrate having the main surface having the sufficiently high mirror surface property cannot be obtained, with the result that it becomes difficult to sufficiently reduce the value of the haze of the epitaxial film grown on the main surface.

In view of the above, it is an object of the present disclosure to provide: a gallium arsenide single crystal substrate to improve a device property by attaining formation of an epitaxial film having a reduced value of haze; and a method of producing the gallium arsenide single crystal substrate.

### Advantageous Effect of the Present Disclosure

According to the present disclosure, it is possible to provide: a gallium arsenide single crystal substrate to improve a device property by attaining formation of an epitaxial film having a reduced value of haze; and a method of producing the gallium arsenide single crystal substrate.

### DESCRIPTION OF EMBODIMENTS

First, an overview of an embodiment of the present disclosure will be described. In order to solve the above-described problem, the present inventors have completed the present disclosure as a result of diligent study. That is, the present inventors have paid attention to obtaining a main surface having a high mirror surface property in a gallium arsenide single crystal substrate by performing a novel cleaning method onto a gallium arsenide single crystal substrate precursor having a circular surface and cut out from a gallium arsenide single crystal. Specifically, in addition to conventionally known liquid phase treatment including both alkali cleaning with an alkaline solution and acid cleaning with an acidic solution, a second alkali cleaning was newly performed and heating treatment was newly performed. As a result, the present inventors have found the following knowledge: in the GaAs single crystal substrate obtained through the above-described novel cleaning method, wettability of the oxide film is improved when the GaAs single crystal substrate has such a composition that the oxide film is richer in gallium than in arsenic as a whole and this tendency is maintained to an interface between the oxide film and the GaAs single crystal of the gallium arsenide single crystal substrate. In this way, the GaAs single crystal substrate having the main surface having the high mirror surface property can be obtained by wet etching to arrive at the GaAs single crystal substrate on which an epitaxial film having a reduced value of haze can be formed, thus completing the present disclosure.

Next, embodiments of the present disclosure will be listed and described.
[1] A gallium arsenide single crystal substrate according to one embodiment of the present disclosure is a gallium arsenide single crystal substrate having a main surface having a circular shape. The gallium arsenide single crystal substrate has a first integrated intensity ratio, a second integrated intensity ratio, a third integrated intensity ratio, a fourth integrated intensity ratio, and a fifth integrated intensity ratio. Each of the first integrated intensity ratio and the third integrated intensity ratio is obtained by determining each of spectra of detection intensities of 3d electrons of gallium and arsenic with respect to binding energy of a photoelectron emitted to outside of the gallium arsenide single crystal substrate based on X-ray photoelectron spectroscopy in which X-ray is applied to a center of the main surface under conditions of an X-ray incident energy of 600 eV and a photoelectron take-off angle of 30°. Each of the second integrated intensity ratio and the fifth integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to the center of the main surface under conditions of an X-ray incident energy of 600 eV and a photoelectron take-off angle of 85°. The fourth integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to the center of the main surface under conditions of an X-ray incident energy of 600 eV and a photoelectron take-off angle of 45°. Each of the first integrated intensity ratio and the second integrated intensity ratio is a ratio of a sum of an integrated intensity of an arsenic element present as diarsenic pentoxide, an integrated intensity of an arsenic element present as diarsenic trioxide, an integrated intensity of an arsenic element present as gallium arsenide, and an integrated intensity of an arsenic element present as a metal arsenic to a sum of an integrated intensity of a gallium element present as digallium monoxide, an integrated intensity of a gallium element present as digallium trioxide, and an integrated intensity of a gallium element present as the gallium arsenide. Each of the third integrated intensity ratio, the fourth integrated intensity ratio, and the fifth integrated intensity ratio is a ratio of a sum of an integrated intensity of the arsenic element present as the diarsenic pentoxide and an integrated intensity of the arsenic element present as the diarsenic trioxide to a sum of an integrated intensity of the gallium element present as the digallium monoxide and an integrated intensity of the gallium element present as the digallium trioxide. The second integrated intensity ratio is 0.9 or more and 1.05 or less. Each of the third integrated intensity ratio and the fourth integrated intensity ratio is 1.0 or less. The fifth integrated intensity ratio is 0.8 or less. A ratio of the first integrated intensity ratio to the second integrated intensity ratio is 0.5 or more and 1 or less.

The gallium arsenide single crystal substrate having such a feature has a main surface having a high mirror surface property because the oxide film can be effectively removed by wet etching, with the result that an epitaxial film having a reduced value of haze can be formed thereon.
[2] The second integrated intensity ratio is preferably 0.9 or more and less than 1.04. Thus, the oxide film can be more effectively removed by wet etching.
[3] The gallium arsenide single crystal substrate preferably has an oxide film having a thickness of 2 nm or less in the main surface. Thus, the oxide film can be more effectively removed by wet etching.
[4]A contact angle of the oxide film is preferably 200 or less. Thus, the oxide film having excellent wettability can be more effectively removed by wet etching.
[5] The gallium arsenide single crystal substrate preferably has a diameter of 75 mm or more and 205 mm or less. Thus, the gallium arsenide single crystal substrate having the diameter of 75 mm or more and 205 mm or less can be provided with the main surface having the high mirror surface property, with the result that an epitaxial film having a reduced value of haze can be formed thereon.
[6] The gallium arsenide single crystal substrate preferably has the following feature. The gallium arsenide single crystal substrate has a diameter of 75 mm or more and less than 150 mm. The gallium arsenide single crystal substrate has a sixth integrated intensity ratio and a seventh integrated intensity ratio. Each of the sixth integrated intensity ratio and the seventh integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to each of five measurement points on the main surface under conditions of an X-ray incident energy of 600 eV and a photoelectron take-off angle of 85°. The sixth integrated intensity ratio is a ratio of a sum of an integrated intensity of the arsenic element present as the diarsenic pentoxide, an integrated intensity of the arsenic element present as the diarsenic trioxide, an integrated intensity of the arsenic element present as the gallium arsenide, and an integrated intensity of the arsenic element present as the metal arsenic to a sum of an integrated intensity of the gallium element present as the digallium monoxide, an integrated intensity of the gallium element present as the digallium trioxide, and an integrated intensity of the gallium element present as the gallium arsenide. The seventh integrated intensity ratio is a ratio of a sum of the integrated intensity of the arsenic element present as the diarsenic pentoxide and the integrated intensity of the arsenic element present as the diarsenic trioxide to a sum of the integrated intensity of the gallium element present as the digallium monoxide and the integrated intensity of the gallium element present as the digallium trioxide. A standard deviation and an average value of a ratio of the seventh integrated intensity ratio to the sixth integrated intensity ratio satisfy a relation of the standard deviation/the average value≤0.039. When the diameter is represented by D and two axes, which each pass through the center of the main surface, are each located on the main surface, and are orthogonal to each other, are defined as an X axis and a Y axis, coordinates (X, Y) of the five measurement points on the X axis and the Y axis are (0, 0), (D/4, 0), (0, D/4), (−D/4, 0), and (0, −D/4) respectively. Units of the D and each of the X and the Y in the coordinates (X, Y) are mm. Thus, since the oxide film is effectively removed using wet etching in the gallium arsenide single crystal substrate having the diameter of 75 mm or more and less than 150 mm, it is possible to obtain a main surface having a high mirror surface property without variation in the plane, with the result that an epitaxial film having a reduced value of haze can be formed thereon.
[7] The gallium arsenide single crystal substrate preferably has the following feature. The gallium arsenide single crystal substrate has a diameter of 150 mm or more and 205 mm or less. The gallium arsenide single crystal substrate has an eighth integrated intensity ratio and a ninth integrated intensity ratio. Each of the eighth integrated intensity ratio and the ninth integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to each of nine measurement points on the main surface under conditions of an X-ray incident energy of 600 eV and a photoelectron take-off angle of 85°. The eighth integrated intensity ratio is a ratio of a sum of an integrated intensity of the arsenic element present as the diarsenic pentoxide, an integrated intensity of the arsenic element present as the diarsenic trioxide, an integrated intensity of the arsenic element present as the gallium arsenide, and an integrated intensity of the arsenic element present as the metal arsenic to a sum of an integrated intensity of the gallium element present as the digallium monoxide, an integrated intensity of the gallium element present as the digallium trioxide, and an integrated intensity of the gallium element present as the gallium arsenide. The ninth integrated intensity ratio is a ratio of a sum of the integrated intensity of the arsenic element present as the diarsenic pentoxide and the integrated intensity of the arsenic element present as the diarsenic trioxide to a sum of the integrated intensity of the gallium element present as the digallium monoxide and the integrated intensity of the gallium element present as the digallium trioxide. A standard deviation and an average value of a ratio of the ninth integrated intensity ratio to the eighth integrated intensity ratio satisfy a relation of the standard deviation/the average value≤0.022. When the diameter is represented by D and two axes, which each pass through the center of the main surface, are each located on the main surface, and are orthogonal to each other, are defined as an X axis and a Y axis, coordinates (X, Y) of the nine measurement points on the X axis and the Y axis are (0, 0), (D/4, 0), (0, D/4), (−D/4, 0), (0, −D/4), (D/2−10, 0), (0, D/2−10), (−(D/2−10), 0), and (0, −(D/2−10)) respectively. Units of the D and each of the X and the Y in the coordinates (X, Y) are mm. Thus, since the oxide film is effectively removed using wet etching in the gallium arsenide single crystal substrate having the diameter of 150 mm or more and 205 mm or less, it is possible to obtain a main surface having a high mirror surface property without variation in the plane, with the result that an epitaxial film having a reduced value of haze can be formed thereon.
[8] Preferably, the gallium arsenide single crystal substrate has an epitaxial film on the main surface, a maximum value of haze of a surface of the epitaxial film is 100 ppm or less, and an average value of the haze of the surface of the epitaxial film is 2.5 ppm or less. Thus, it is possible to provide the gallium arsenide single crystal substrate having the main surface on which the epitaxial film having a reduced value of haze is formed.
[9] A method of producing a gallium arsenide single crystal substrate according to one embodiment of the present disclosure is a method of producing a gallium arsenide single crystal substrate having a main surface having a circular shape. The method includes: preparing a gallium arsenide single crystal substrate precursor having a surface having a circular shape; and obtaining the gallium arsenide single crystal substrate from the gallium arsenide single crystal substrate precursor. The obtaining includes: forming the surface of the gallium arsenide single crystal substrate precursor into a polished surface by polishing the surface; forming the polished surface into an alkali-cleaned surface by cleaning the polished surface with a first alkali cleaning liquid; forming the alkali-cleaned surface into an acid-cleaned surface by cleaning the alkali-cleaned surface with an acid cleaning liquid including 0.3 mass ppm or more and 0.5 mass % or less of an acid; forming the acid-cleaned surface into a second alkali-cleaned surface by cleaning the acid-cleaned surface by supplying a second alkali cleaning liquid to the acid-cleaned surface at a flow rate of 0.1 L/minute or more and 5 L/minute or less for 30 seconds or more and 5 minutes or less while rotating the acid-cleaned surface at a rotation speed of 1000 rpm or more in a peripheral direction; and forming the second alkali-cleaned surface into the main surface by performing heat treatment onto the second alkali-cleaned surface in an inert gas atmosphere under conditions of 1.1 atmospheric pressures or more and 3 atmospheric pressures or less and 150° C. or more and 300° C. or less. The first alkali cleaning liquid includes 0.1 mass % or more and 10 mass % or less of a first base. The first base at least includes one of a quaternary ammonium hydroxide and a quaternary pyridinium hydroxide. The second alkali cleaning liquid includes 0.3 mass ppm or more and 0.5 mass % or less of a second base. The second base at least includes one of the quaternary ammonium hydroxide and the quaternary pyridinium hydroxide. According to the method of producing a gallium arsenide single crystal substrate with such a feature, the gallium arsenide single crystal substrate having the main surface having the high mirror surface property can be obtained.
[10] Preferably, the method include forming an epitaxial film on the main surface. Thus, an epitaxial film having a reduced value of haze can be formed on the main surface.

### Details of Embodiments

Hereinafter, one embodiment (hereinafter, also referred to as “the present embodiment”) according to the present disclosure will be described more in detail, but the present disclosure is not limited thereto. Although explanation will be made in the description below with reference to figures, the same or corresponding elements will be denoted by the same reference characters in the present specification and figures, and the same explanation therefor will not be described repeatedly. Moreover, in each of the figures, the scale of each component is appropriately adjusted in order to facilitate understanding, and the scale of each component shown in each of the figures does not necessarily coincide with the actual scale of the component.

In the present specification, the expression “A to B” represents a range of lower to upper limits (i.e., A or more and B or less), and when no unit is indicated for A and a unit is indicated only for B, the unit of A is the same as the unit of B. Moreover, when a compound or the like is expressed by a chemical formula in the present specification and an atomic ratio is not particularly limited, it is assumed that all the conventionally known atomic ratios are included, and the atomic ratio should not be necessarily limited only to one in the stoichiometric range.

In the present specification, the term “main surface” of a gallium arsenide single crystal substrate means each of two circular surfaces of the substrate. When at least one of the two surfaces satisfies the scope of claims with regard to the present disclosure in the gallium arsenide single crystal substrate, the gallium arsenide single crystal substrate falls within the scope of the present invention. An epitaxial film may be disposed on the “main surface” of the gallium arsenide single crystal substrate. Moreover, in the present specification, the term “plane” used in the expression “in-plane” or “in the plane” means the “main surface”. Further, when it is described that the diameter of the gallium arsenide single crystal substrate is “75 mm”, it means that the diameter is about 75 mm (about 75 to 76.5 mm) or 3 inches. When it is described that the diameter is “100 mm”, it means that the diameter is about 100 mm (about 95 to 105 mm) or 4 inches. When it is described that the diameter is “150 mm”, it means that the diameter is about 150 mm (about 145 to 155 mm) or 6 inches. When it is described that the diameter is “200 mm”, it means that the diameter is about 200 mm (about 195 to 205 mm) or 8 inches. It should be noted that the diameter can be measured by using a conventionally known outer diameter measurement device such as a caliper.

Regarding crystallographic indications in the present specification, an individual orientation is represented by [ ], a group orientation is represented by < >, and an individual plane is represented by ( ), and a group plane is represented by { }. Moreover, a negative crystallographic index is normally expressed by putting “-” (bar) above a numeral, but is expressed by putting the negative sign before the numeral when stated in the present specification.

### [Gallium Arsenide Single Crystal Substrate]

The gallium arsenide single crystal substrate (GaAs single crystal substrate) according to the present embodiment is a GaAs single crystal substrate having a main surface having a circular shape. The GaAs single crystal substrate has a first integrated intensity ratio, a second integrated intensity ratio, a third integrated intensity ratio, a fourth integrated intensity ratio, and a fifth integrated intensity ratio. Each of the first integrated intensity ratio and the third integrated intensity ratio is obtained by determining each of spectra of detection intensities of 3d electrons of gallium (Ga) and arsenic (As) with respect to binding energy of a photoelectron emitted to outside of the GaAs single crystal substrate based on X-ray photoelectron spectroscopy in which X-ray is applied to a center of the main surface under conditions of an X-ray incident energy of 600 eV and a photoelectron take-off angle of 30°. Each of the second integrated intensity ratio and the fifth integrated intensity ratio is obtained by determining each of spectra of detection intensities of 3d electrons of the Ga and the As with respect to binding energy of a photoelectron emitted to the outside of the GaAs single crystal substrate based on X-ray photoelectron spectroscopy in which X-ray is applied to the center of the main surface under conditions of an X-ray incident energy of 600 eV and a photoelectron take-off angle of 85°. The fourth integrated intensity ratio is obtained by determining each of spectra of detection intensities of 3d electrons of the Ga and the As with respect to binding energy of a photoelectron emitted to the outside of the GaAs single crystal substrate based on X-ray photoelectron spectroscopy in which X-ray is applied to the center of the main surface under conditions of an X-ray incident energy of 600 eV and a photoelectron take-off angle of 45°.

Each of the first integrated intensity ratio and the second integrated intensity ratio is a ratio of a sum of an integrated intensity of an As element (hereinafter, also referred to as “As⁵⁺” for ease of description) present as diarsenic pentoxide (As₂O₅), an integrated intensity of an As element (hereinafter, also referred to as “As³⁺” for ease of description) present as diarsenic trioxide (As₂O₃), an integrated intensity of an As element (hereinafter, also referred to as “As—Ga” for ease of description) present as gallium arsenide (GaAs), and an integrated intensity of an As element (hereinafter, also referred to as “metal As” for ease of description) present as a metal arsenic (metal As) to a sum of an integrated intensity of a Ga element (hereinafter, also referred to as “Ga⁺” for ease of description) present as digallium monoxide (Ga₂O), an integrated intensity of a Ga element (hereinafter, also referred to as “Ga³⁺” for ease of description) present as digallium trioxide (Ga₂O₃), and an integrated intensity of a Ga element (hereinafter, also referred to as “Ga—As” for ease of description) present as the gallium arsenide (GaAs). Each of the third integrated intensity ratio, the fourth integrated intensity ratio, and the fifth integrated intensity ratio is a ratio of a sum of an integrated intensity of the As element (As⁵⁺) present as the As₂O₅ and an integrated intensity of the As element (As³⁺) present as the As₂O₃ to a sum of an integrated intensity of the Ga element (Ga⁺) present as the Ga₂O and an integrated intensity of the Ga element (Ga³⁺) present as the Ga₂O₃. In the GaAs single crystal substrate, the second integrated intensity ratio is 0.9 or more and 1.05 or less. Each of the third integrated intensity ratio and the fourth integrated intensity ratio is 1.0 or less. The fifth integrated intensity ratio is 0.8 or less. Further, a ratio of the first integrated intensity ratio to the second integrated intensity ratio is 0.5 or more and 1 or less.

By effectively removing an oxide film using wet etching, the GaAs single crystal substrate having such a feature can have a main surface having a high mirror surface property. Therefore, an epitaxial film having a reduced value of haze can be formed thereon.

### <Main Surface>

The GaAs single crystal substrate has the main surface having the circular shape as described above. In the present specification, the “circular shape” representing the shape of the main surface includes not only a geometric circular shape but also a shape when the main surface does not form the geometric circular shape due to formation of at least one of a notch, an orientation flat (hereinafter, also referred to as “OF”), and an index flat (hereinafter, also referred to as “IF”). That is, the “shape when the main surface does not form the geometric circular shape” means a shape when the length of a line segment extending from any point on the notch, OF, and IF to the center of the main surface becomes short among line segments extending from any point on the outer periphery of the main surface to the center of the main surface. In other words, in the present specification, the main surface is said to have the “circular shape” based on the shape before the notch, OF, and IF are formed. Therefore, the position of the center of the main surface and the size (length) of the diameter of the substrate are determined based on the circular shape before the notch, OF, IF, and the like are formed. It should be noted that the “shape when the main surface does not form the geometric circular shape” also includes a shape when the lengths of all the line segments extending from any point on the outer periphery of the main surface to the center of the main surface are not necessarily the same due to the shape of the GaAs single crystal before being cut out as the GaAs single crystal substrate. In this case, the center of the main surface refers to the position of the center of gravity, and the diameter of the substrate refers to the length of the longest line segment among the line segments each extending from one point on the outer periphery of the substrate to another point on the outer periphery of the substrate via the center of the main surface.

### <X-Ray Photoelectron Spectroscopy (XPS) Using Synchrotron Radiation>

During development of the GaAs single crystal substrate on which an epitaxial film having a reduced value of haze can be formed, the present inventors have paid attention to X-ray photoelectron spectroscopy (XPS) using synchrotron radiation, by which the state of the main surface of the GaAs single crystal substrate can be analyzed with high precision. Specifically, the XPS using synchrotron radiation has been performed so as to attempt to specify a cause of deterioration of the mirror surface property of the main surface of the GaAs single crystal substrate and eliminate the cause in order to arrive at the GaAs single crystal substrate on which an epitaxial film having a reduced value of haze can be formed. Here, the XPS refers to an analysis method in which X-ray is applied to a sample and kinetic energy distribution of photoelectrons emitted from the sample is measured so as to obtain knowledge about types, abundances, chemical bonding states, and the like of elements present in a surface of the sample.

In general, when the main surface of the GaAs single crystal substrate is analyzed by the XPS, the XPS is often performed using X-ray having energy fixed to around 1.487 keV. However, when the X-ray having incident energy fixed to around 1.487 keV is used and a photoelectron take-off angle is 30°, the knowledge about the state of the main surface of the GaAs single crystal substrate is obtained as a state of average in a region from the main surface to a depth of about 5 nm. This region corresponds to about 20 atomic layers when converted into atomic layers. For this reason, in the XPS, it becomes difficult to analyze the state of the main surface of the GaAs single crystal substrate with high precision. Further, when the X-ray having incident energy fixed to around 1.487 keV is used and the photoelectron take-off angle is deviated in the XPS so as to obtain knowledge about the state of the main surface of the GaAs single crystal substrate, a measurement error with respect to the angle becomes too large and a measurement error also becomes large due to a small ionization efficiency of the photoelectron intensity, with the result that it is also difficult to perform the analysis with high precision.

On the other hand, in the present disclosure, since the XPS is performed under conditions that the X-ray having an X-ray incident energy of 600 eV is used and the photoelectron take-off angle is set to 30°, 45°, or 85° as described above, the state of the main surface of the GaAs single crystal substrate can be analyzed.

When the X-ray incident energy is set to 600 eV and the photoelectron take-off angle is set to 300 as the conditions for performing the XPS, the knowledge about the state of the main surface of the GaAs single crystal substrate can be obtained as a state of average in a region from the main surface to a depth of about 2.25 nm. When the X-ray incident energy is set to 600 eV and the photoelectron take-off angle is set to 45° as the conditions for performing the XPS, the knowledge about the state of the main surface of the GaAs single crystal substrate is obtained as a state of average in a region from the main surface to a depth of about 3.18 nm. When the X-ray incident energy is set to 600 eV and the photoelectron take-off angle is set to 85° as the conditions for performing the XPS, the knowledge about the state of the main surface of the GaAs single crystal substrate can be obtained as a state of average in a region from the main surface to a depth of about 4.48 nm. That is, the region from the main surface of the GaAs single crystal substrate to the depth of about 5 nm (corresponding to about 20 atomic layers) can be analyzed in detail for about every one to three atomic layers, with the result that the state of the main surface can be analyzed more precisely than in the conventional art.

It has been known that an oxide film having a thickness of about 1 to 2 nm is formed in the main surface of the GaAs single crystal substrate after cleaned by a cleaning step. Therefore, attempts have been made to form an epitaxial film on the main surface after removing the oxide by wet etching, so as to reduce a value of haze of a surface of the epitaxial film. However, for example, a portion of the oxide film remains in the main surface even after the wet etching, with the result that the value of the haze of the surface of the epitaxial film is large to some extent. To address this, the present inventors have paid attention to analyzing, in a detailed manner by the above-described XPS using synchrotron radiation, the vicinity of an interface (i.e., region at a depth of about 2 to 5 nm from the main surface of the GaAs single crystal substrate) between the oxide film occupying the top surface of the main surface of the GaAs single crystal substrate and a layer (hereinafter, also referred to as a “main layer” of the GaAs single crystal substrate) composed of gallium (Ga) and arsenic (As) and located directly below the oxide film. As a result, the present inventors have found the following knowledge: wettability of the oxide film becomes excellent when the GaAs single crystal substrate has such a composition that the oxide film is richer in gallium than in arsenic as a whole and this tendency is maintained to the interface between the oxide film and the GaAs single crystal in the GaAs single crystal substrate, with the result that the oxide film can be effectively removed by the wet etching. That is, the present inventors have conceived to appropriately control the gallium composition in the oxide film so as to obtain the main surface having the high mirror surface property. It should be noted that in the present specification, the “surface” of the oxide film refers to a surface of the oxide film opposite to the GaAs single crystal substrate side.

### <First Integrated Intensity Ratio, Second Integrated Intensity Ratio, Third Integrated Intensity Ratio, Fourth Integrated Intensity Ratio, and Fifth Integrated Intensity Ratio>

The GaAs single crystal substrate according to the present embodiment has the first integrated intensity ratio, the second integrated intensity ratio, the third integrated intensity ratio, the fourth integrated intensity ratio, and the fifth integrated intensity ratio. Each of the first integrated intensity ratio and the third integrated intensity ratio is obtained by determining each of the spectra of the detection intensities of the 3d electrons of the Ga and the As with respect to the binding energy of the photoelectron emitted to the outside of the GaAs single crystal substrate based on the X-ray photoelectron spectroscopy in which X-ray is applied to the center of the main surface under the conditions of an X-ray incident energy of 600 eV and a photoelectron take-off angle of 30°. Each of the second integrated intensity ratio and the fifth integrated intensity ratio is obtained by determining each of the spectra of the detection intensities of the 3d electrons of the Ga and the As with respect to the binding energy of the photoelectron emitted to the outside of the GaAs single crystal substrate based on the X-ray photoelectron spectroscopy in which X-ray is applied to the center of the main surface under the conditions of an X-ray incident energy of 600 eV and a photoelectron take-off angle of 85°. The fourth integrated intensity ratio is obtained by determining each of the spectra of the detection intensities of the 3d electrons of the Ga and the As with respect to the binding energy of the photoelectron emitted to the outside of the GaAs single crystal substrate based on the X-ray photoelectron spectroscopy in which X-ray is applied to the center of the main surface under the conditions of an X-ray incident energy of 600 eV and a photoelectron take-off angle of 45°.

Each of the first integrated intensity ratio and the second integrated intensity ratio is the ratio of the sum of the integrated intensity of the As element (As⁵⁺) present as the As₂O₅, the integrated intensity of the As element (As³⁺) present as the As₂O₃, the integrated intensity of the As element (As—Ga) present as the GaAs, and the integrated intensity of the As element (metal As) present as the metal As to the sum of the integrated intensity of the Ga element (Ga⁺) present as the Ga₂O, the integrated intensity of the Ga element (Ga³⁺) present as the Ga₂O₃, and the integrated intensity of the Ga element (Ga—As) present as the GaAs. Each of the third integrated intensity ratio, the fourth integrated intensity ratio, and the fifth integrated intensity ratio is the ratio of the sum of the integrated intensity of the As element (As⁵⁺) present as the As₂O₅ and the integrated intensity of the As element (As³⁺) present as the As₂O₃ to the sum of the integrated intensity of the Ga element (Ga³⁺) present as the Ga₂O and the integrated intensity of the Ga element (Ga³⁺) present as the Ga₂O₃.

When the first integrated intensity ratio, the second integrated intensity ratio, the third integrated intensity ratio, the fourth integrated intensity ratio, and the fifth integrated intensity ratio are respectively expressed by In1, In2, In3, In4, and In5, In1, In2, In3, In4, and In5 can be respectively represented by the following mathematical formulas.

$$ln 1 = \frac{I ( {As}_{2} {O}_{5} ) + I ( {As}_{2} {O}_{3} ) + I ( As\_Ga ) + I ( As )}{I ( {Ga}_{2} O ) + I ( {Ga}_{2} {O}_{3} ) + I ( Ga\_As )} \qquad [ Math . 1 ]$$

$$ln 2 = \frac{I ( {As}_{2} {O}_{5} ) + I ( {As}_{2} {O}_{3} ) + I ( As\_Ga ) + I ( As )}{I ( {Ga}_{2} O ) + I ( {Ga}_{2} {O}_{3} ) + I ( Ga\_As )}$$

$$ln 3 = \frac{I ( {As}_{2} {O}_{5} ) + I ( {As}_{2} {O}_{3} )}{I ( {Ga}_{2} O ) + I ( {Ga}_{2} {O}_{3} )}$$

$$ln 4 = \frac{I ( {As}_{2} {O}_{5} ) + I ( {As}_{2} {O}_{3} )}{I ( {Ga}_{2} O ) + I ( {Ga}_{2} {O}_{3} )}$$

$$ln 5 = \frac{I ( {As}_{2} {O}_{5} ) + I ( {As}_{2} {O}_{3} )}{I ( {Ga}_{2} O ) + I ( {Ga}_{2} {O}_{3} )}$$

In the GaAs single crystal substrate, the second integrated intensity ratio is 0.9 or more and 1.05 or less. Each of the third integrated intensity ratio and the fourth integrated intensity ratio is 1.0 or less. The fifth integrated intensity ratio is 0.8 or less. Further, the ratio of the first integrated intensity ratio to the second integrated intensity ratio is 0.5 or more and 1 or less. The second integrated intensity ratio is preferably 0.9 or more and less than 1.04.

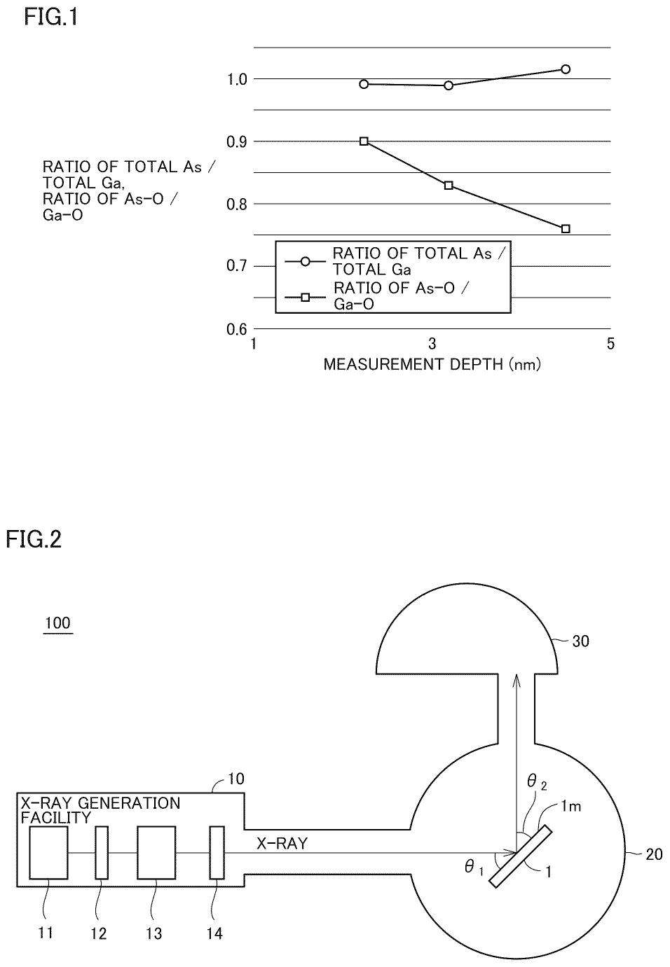

FIG. 1 is an exemplary graph showing a relation between a measurement depth (horizontal axis) from the main surface of the GaAs single crystal substrate according to the present embodiment and each of the ratio (vertical axis) of the integrated intensity of the total of the arsenic element to the integrated intensity of the total of the gallium element and the ratio (vertical axis) of the integrated intensity of the arsenic element present as the arsenic oxide to the integrated intensity of the gallium element present as the gallium oxide. In FIG. 1, a point indicated by a circle around a measurement depth (horizontal axis) of about 2.25 nm corresponds to the first integrated intensity ratio, and a point indicated by a circle around a measurement depth (horizontal axis) of about 4.48 nm corresponds to the second integrated intensity ratio. A point indicated by a rectangle around the measurement depth (horizontal axis) of about 2.25 nm corresponds to the third integrated intensity ratio, a point indicated by a rectangle around a measurement depth (horizontal axis) of about 3.18 nm corresponds to the fourth integrated intensity ratio, and a point indicated by a rectangle around the measurement depth (horizontal axis) of about 4.48 nm corresponds to the fifth integrated intensity ratio.

In FIG. 1, the first integrated intensity ratio, the second integrated intensity ratio, the third integrated intensity ratio, the fourth integrated intensity ratio, and the fifth integrated intensity ratio are 0.99, 1.01, 0.9, 0.83, and 0.76, respectively. Further, the ratio of the first integrated intensity ratio to the second integrated intensity ratio is 0.98 (=0.99/1.01).

Such a relation means attainment of such a composition that the oxide film occupying from the main surface to the depth of about 1 to 2 nm is richer in gallium than in arsenic as a whole and this tendency is maintained to the interface (depth of about 2 to 5 nm from the main surface) between the main layer and the oxide film. Specifically, when the second integrated intensity ratio is 0.9 or more and 1.05 or less, it means that the thickness of the oxide film is an intended thickness and the thickness of the oxide film is not thicker than the intended thickness. When each of the third integrated intensity ratio and the fourth integrated intensity ratio is 1.0 or less, it means that the oxide film is richer in gallium than in arsenic as a whole. When the fifth integrated intensity ratio is 0.8 or less and the ratio of the first integrated intensity ratio to the second integrated intensity ratio is 0.5 or more and 1 or less, it means that a change of the composition is steep at the interface between the main layer and the oxide film and the composition in which the oxide film is richer in gallium than in arsenic is maintained to the vicinity of the interface. In this case, it is presumed that since the wettability of the surface of the oxide film is excellent, the oxide film can be effectively removed by wet etching. Thus, when an epitaxial film is grown on the main surface of the GaAs single crystal substrate according to the present embodiment after the wet etching, both maximum value and average value of haze of a surface of the epitaxial film can be smaller than those in the conventional art (for example, the maximum value of the haze of the surface of the epitaxial film can be 100 ppm or less, and the average value of the haze can be 2.5 ppm or less). In the present specification, the “surface” of the epitaxial film refers to a surface of the epitaxial film opposite to the GaAs single crystal substrate side.

On the other hand, when each of the first integrated intensity ratio, the second integrated intensity ratio, the third integrated intensity ratio, the fourth integrated intensity ratio, and the fifth integrated intensity ratio is obtained by performing the XPS onto the conventional GaAs single crystal substrate, any one of the following relations is not satisfied. That is, the second integrated intensity ratio does not satisfy the relation of 0.9 or more and 1.05 or less, each of the third integrated intensity ratio and the fourth integrated intensity ratio does not satisfy the relation of 1.0 or less, the fifth integrated intensity ratio does not satisfy the relation of 0.8 or less, or the ratio of the first integrated intensity ratio to the second integrated intensity ratio does not satisfy the relation of 0.5 or more and 1 or less. In such a GaAs single crystal substrate, a portion of the oxide film may remain in the main surface even after the wet etching. Therefore, when an epitaxial film is formed on the main surface of the GaAs single crystal substrate after the wet etching, a level difference is caused in the surface, with the result that the maximum value and average value of the haze may become large.

As described above, the present inventors have first found that the haze of the surface of the epitaxial film formed on the main surface of the GaAs single crystal substrate depends on the amount of gallium to the amount of arsenic and the amount of gallium oxide to the amount of arsenic oxide in each of the oxide film (region occupying from the main surface to the depth of about 1 to 2 nm) and the vicinity of the interface (region at the depth of 2 to 5 nm from the main surface) between the oxide film and the main layer.

### <Oxide Film>

The GaAs single crystal substrate preferably has an oxide film having a thickness of 2 nm or less in the main surface. Thus, the oxide film can be more effectively removed by wet etching. The thickness of the oxide film is more preferably 1.5 nm or less. The lower limit of the thickness of the oxide film is not particularly limited, but is, for example, 0.5 nm.

The thickness of the oxide film can be determined by analyzing the main surface of the GaAs single crystal substrate using a scanning transmission electron microscope (STEM; for example, trade name (product number): “JEM-ARM300F2” provided by JEOL) accompanied with an energy dispersive X-ray spectrometer (EDX: Energy Dispersive X-ray Spectroscopy). Specifically, by applying an electron beam to the center of the main surface of the GaAs single crystal substrate under a condition of an acceleration voltage of 200 kV, characteristic X-ray specific to an element and generated at the center of the main surface is divided and detected using the EDX, thereby performing a composition analysis. By performing a line analysis thereonto along the depth direction of the main surface, a composition corresponding to each of analysis depths from the surface of the main surface is determined.

Further, the thickness of the oxide film can be determined as follows from the composition analysis described above. That is, first, a difference between the content of the As and the content of the Ga is determined along each analysis depth from the surface of the main surface, and a spectrum is drawn on a graph with the horizontal axis representing the analysis depth and the vertical axis representing the difference. Next, since the spectrum indicates a shape having a peak similar to the Gaussian distribution, the half width of the shape is determined and can be regarded as the thickness of the oxide film. As described above, the GaAs single crystal substrate according to the present embodiment has the composition rich in gallium (particularly gallium oxide) in each of the oxide film and the vicinity of the interface (region to a depth of 1 to 5 nm from the main surface) between the oxide film and the main layer. Therefore, based on the difference between the content of the As and the content of the Ga along the analysis depth from the surface of the main surface, the thickness of the oxide film can be determined from the spectrum indicating the difference.

### <Wettability (Contact Angle)>

The contact angle of the oxide film is preferably 200 or less. Thus, the oxide film has excellent wettability and therefore can be more effectively removed by wet etching. The contact angle of the oxide film is more preferably 100 or less. The lower limit value of the contact angle of the oxide film is not particularly limited, but is, for example, 1°.

The contact angle of the oxide film can be determined in the following manner: 2 μL of distilled water is dropped onto the center of the main surface (the surface of the oxide film) under an environment of room temperature (20 to 25° C.) and relative humidity of 40 to 60% and the contact angle of a droplet of the distilled water as formed on the center of the main surface is measured using the θ/2 method. A contact angle meter (for example, trade name (product number): “Drop Master 500” provided by Kyowa Interface Science) can be used for the observation of the droplet.

### <Diameter>

The GaAs single crystal substrate preferably has a diameter of 75 mm or more and 205 mm or less. In other words, the diameter of the GaAs single crystal substrate is preferably 3 to 8 inches. Thus, in the GaAs single crystal substrate having the diameter of 75 mm or more and 205 mm or less, the main surface having the high mirror surface property can be obtained by effectively removing the oxide film using wet etching. Here, even when the substrate has a shape that does not form a geometric circular shape due to influence of the OF, IF, or the like, the size (diameter) of the substrate is determined on such an assumption that the substrate has a circular shape before the formation of the OF, IF, or the like. The GaAs single crystal substrate preferably has a diameter of 100 mm or more and 205 mm or less, and more preferably has a diameter of 150 mm or more and 205 mm or less.

### <Method of Analyzing GaAs Single Crystal Substrate by X-Ray Photoelectron Spectroscopy (XPS) Using Synchrotron Radiation>

Hereinafter, the method of analyzing the GaAs single crystal substrate by the XPS using synchrotron radiation will be described more in detail.

### (Analysis System)

FIG. 2 is an explanatory diagram schematically illustrating a configuration of an analysis system using the X-ray photoelectron spectroscopy. As shown in FIG. 2, an analysis system 100 includes an X-ray generation facility 10, a vacuum container 20, and an electron spectrometer 30. X-ray generation facility 10, vacuum container 20, and electron spectrometer 30 are coupled together in this order. An internal space of each of X-ray generation facility 10, vacuum container 20, and electron spectrometer 30 is maintained in ultrahigh vacuum. A pressure in the internal space of each of X-ray generation facility 10, vacuum container 20, and electron spectrometer 30 is, for example, 4×10⁻⁷ Pa.

X-ray generation facility 10 generates X-ray, which is referred to as synchrotron radiation. As X-ray generation facility 10, for example, the beamline “BL17” in SAGA Light Source can be used.

X-ray generation facility 10 can generate X-ray having any energy in a range of 50 to 2000 eV in the “BL17” so as to apply the X-ray to GaAs single crystal substrate 1 placed in vacuum container 20. X-ray generation facility 10 illustrated in FIG. 2 has an X-ray source 11, slits 12, 14, and a grating 13. Slits 12, 14 are disposed on the upstream side and the downstream side with respect to grating (spectrometer) 13, respectively. Each of slits 12, 14 is, for example, a four-quadrant slit.

By bending a traveling direction of high-energy electron using a magnetic field generated by a bending electromagnet in a circular accelerator, X-ray source 11 outputs synchrotron radiation (X-ray) emitted in a direction along a line tangential to the traveling direction.

The X-ray emitted from X-ray source 11 has high luminance. Specifically, the number of photons of the X-ray emitted from X-ray source 11 per second is 10⁹ photons/s. However, the luminance (intensity) of the X-ray emitted from X-ray source 11 is attenuated with passage of time. For example, the luminance of the X-ray emitted 11 hours after activation of X-ray source 11 is ⅓ of the luminance of the X-ray emitted immediately after the activation thereof.

The X-ray emitted from X-ray source 11 is collimated by a collimating mirror (not shown) or the like. Slit 12 allows a part of the collimated X-ray to pass therethrough. The X-ray having passed through slit 12 is monochromatized by grating 13. Slit 14 limits the breadth of the monochromatized X-ray.

The energy of the X-ray emitted from X-ray generation facility 10 is determined by the slit widths of slits 12, 14 and the line density of grating 13. For example, the X-ray of 600 eV is emitted from X-ray generation facility 10 by adjusting an emission angle in the grating using grating 13 in which the slit width of each of slits 12, 14 is 30 μm and the line density at the center is 400 l/mm.

When the X-ray from X-ray generation facility 10 is applied to GaAs single crystal substrate 1 placed in vacuum container 20, photoelectrons are emitted from GaAs single crystal substrate 1.

Electron spectrometer 30 measures a kinetic energy distribution of the photoelectrons emitted from GaAs single crystal substrate 1. Electron spectrometer 30 has a hemispherical analyzer and a detector. The hemispherical analyzer divides the photoelectrons. The detector counts the number of photoelectrons of each energy.

An angle θ1 formed by the traveling direction of the X-ray incident on GaAs single crystal substrate 1 from X-ray generation facility 10 and main surface 1m of GaAs single crystal substrate 1 is variable. Further, an angle (hereinafter, referred to as “take-off angle θ₂”) formed by the traveling direction of the photoelectron captured by electron spectrometer 30 among the photoelectrons emitted from GaAs single crystal substrate 1 and main surface 1m of GaAs single crystal substrate 1 is also variable. In the present embodiment, take-off angle θ₂ is set to 30°, 45°, or 85°. Angle θ₁ is not particularly limited, but is set to, for example, 85°.

As electron spectrometer 30, for example, a high-resolution XPS analyzer “R3000” provided by Scienta Omicron can be used.

(Depth from Main Surface for Analysis)

Part of the photoelectrons emitted to the outside of GaAs single crystal substrate 1 in response to the application of the X-ray lose its energy due to inelastic scattering. Therefore, only part of the photoelectrons generated in GaAs single crystal substrate 1 exit into the vacuum while maintaining the energy as large as that when generated, and reaches electron spectrometer 30. The photoelectrons to exit from the surface are generated at a depth corresponding to a depth about three times as large as the inelastic mean free path (IMFP) of the photoelectrons. Therefore, depth d (nm) from the main surface of the GaAs single crystal substrate for analysis is expressed by the following mathematical formula. In the following mathematical formula, λ (nm) represents the IMFP value, and θ₂ represents the take-off angle.

$$d = 3 λ sin {θ}_{2} \qquad [ Math . 2 ]$$

Further, as indicated in “‘Method of Estimating Inelastic Mean Free Path of Electrons by Tpp-2M Formula’, Journal of Surface Analysis, Vol. 1, No. 2, 1995”, k (Å) is represented by the following mathematical formulas.

$$λ = \frac{E}{{E}_{p}^{2} [ β ln ( γ E ) - C / E + D / {E}^{2} ]} \qquad [ Math . 3 ]$$

$${E}_{p} = 28.8 {( \frac{{N}_{v} ρ}{{A}_{w}} )}^{1 / 2}$$

$$β = - 0.10 + \frac{0.944}{{( {E}_{p}^{2} + {E}_{g}^{2} )}^{\frac{1}{2}}} + 0.069 {ρ}^{0.1}$$

$$γ = 0. 191 {ρ}^{- 0.50}$$

$$C = 1. 97 - 0.94 U$$

$$D = 53.4 - 20 \text{.8} U$$

$$U = \frac{{N}_{v} ρ}{{A}_{w}} = \frac{{E}_{p}^{2}}{829.4}$$

In each of the above mathematical formulas, Aw represents atomic weight or molecular weight, N, represents the number of valence electrons per atom or molecule, Ep represents plasmon energy (eV) of free electron, p represents density (g/cm³), and E_{g} represents band gap energy (eV). E represents kinetic energy (eV) of the photoelectrons, and is calculated from the energy (eV) of the applied X-ray and the binding energy (eV) between the electron and the atomic nucleus.

Depth d (nm) from the main surface of the GaAs single crystal substrate for analysis can be determined by using each of the above mathematical formulas. That is, depth d (nm) from the main surface of the GaAs single crystal substrate is calculated by using each of the above mathematical formulas, various parameter values for the 3d electrons of the Ga element and the As element, and the X-ray energy (600 eV). Depth d (nm) is as follows.

When the X-ray incident energy is 600 eV and the photoelectron take-off angle is 30°, depth d is about 2.25 nm. When the X-ray incident energy is 600 eV and the photoelectron take-off angle is 45°, depth d is about 3.18 nm. When the X-ray incident energy is 600 eV and the photoelectron take-off angle is 85°, depth d is about 4.48 nm.

### (Method of Calculating First Integrated Intensity Ratio, Second Integrated Intensity Ratio, Third Integrated Intensity Ratio, Fourth Integrated Intensity Ratio, and Fifth Integrated Intensity Ratio)

Regarding a method of calculating each of the first integrated intensity ratio, the second integrated intensity ratio, the third integrated intensity ratio, the fourth integrated intensity ratio, and the fifth integrated intensity ratio in the main surface based on the above XPS, the following first illustratively describes a method of calculating each of the first integrated intensity ratio and the third integrated intensity ratio. In this case, the XPS is performed onto the center of the main surface of the GaAs single crystal substrate using X-ray having an energy of 600 eV. On this occasion, the photoelectron take-off angle is 30°. Thus, the kinetic energy distribution of the photoelectrons emitted from the GaAs single crystal substrate is obtained.

Kinetic energy E of the photoelectrons emitted from the GaAs single crystal substrate is expressed by the following mathematical formula using energy hv (eV) of the applied X-ray, binding energy E_{B} (eV) of electrons in the GaAs single crystal substrate, and a work function φ (eV).

$$E = h v - {E}_{B} - φ .$$

From the kinetic energy distribution of the photoelectrons emitted from the GaAs single crystal substrate, a spectrum indicating the binding energy distribution of the photoelectrons is generated using the above mathematical formula. In the present embodiment, a Ga3d spectrum and an As3d spectrum each indicating the binding energy distribution of the photoelectrons are generated based on the kinetic energy distribution of the photoelectrons emitted from the position at depth d (nm) from the main surface of the GaAs single crystal substrate. Here, in the present specification, the “Ga3d spectrum” refers to a spectrum representing a detection intensity of each photoelectron emitted from the 3d orbital of the Ga element (the Ga₂O, the Ga₂O₃, and the Ga included in the GaAs). The “As3d spectrum” refers to a spectrum representing a detection intensity of each photoelectron emitted from the 3d orbital of the As element (the As₂O₅, the As₂O₃, the metal As, and the As included in the GaAs).

In particular, in the analysis according to the XPS, from the viewpoint of precise measurement, each of the Ga3d spectrum and the As3d spectrum is obtained by performing narrow scanning in a predetermined range of binding energy. Specifically, by performing narrow scanning in a range of binding energy of 16 to 26 eV, the Ga3d spectrum can be represented in a graph with the horizontal axis representing the range and the vertical axis representing the detection intensity. By performing narrow scanning in a range of binding energy of 39 to 49 eV, the As3d spectrum can be represented in a graph with the horizontal axis representing the range and the vertical axis representing the detection intensity.

The narrow scanning is performed under conditions that an energy interval is 0.05 eV, an integration time at each energy value is 100 ms, and the number of times of integrations is one or more. Further, an energy resolution E/AE is 3480.

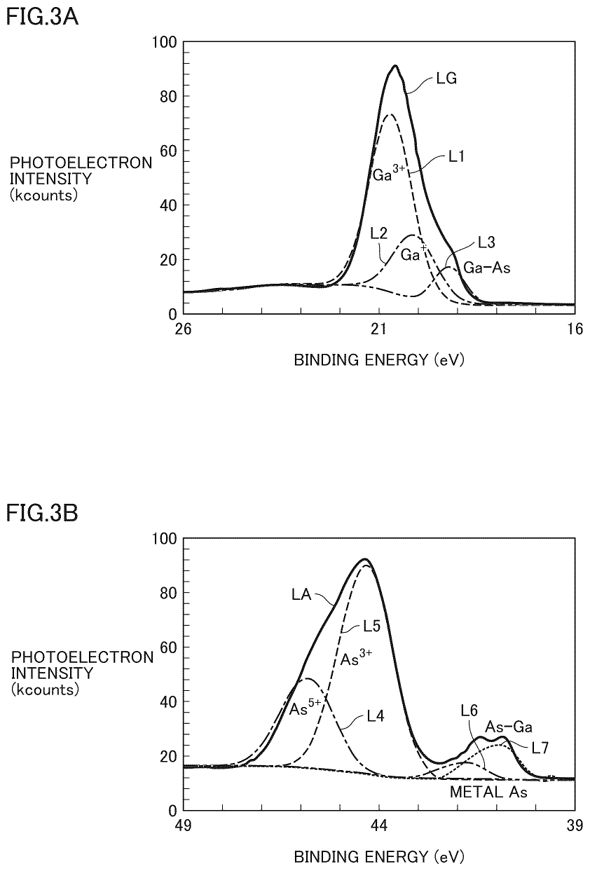

In this way, a Ga3d spectrum LG as shown in FIG. 3A and an As3d spectrum LA as shown in FIG. 3B can be obtained. FIG. 3A is a graph showing an exemplary Ga3d spectrum after background correction as obtained based on the XPS in which X-ray is applied to the center of the main surface of the GaAs single crystal substrate according to the present embodiment. FIG. 3B is a graph showing an exemplary As3d spectrum after background correction as obtained based on the XPS in which X-ray is applied to the center of the main surface of the GaAs single crystal substrate according to the present embodiment. Here, as described above, FIG. 3A and FIG. 3B show the exemplary Ga3d spectrum and As3d spectrum after background correction, respectively. That is, when obtaining each of Ga3d spectrum LG and As3d spectrum LA, the background correction is performed by using the Shirley method (reference document: Kazuhiro Yoshihara: Journal of the Vacuum Society of Japan, 2013, Vol. 56, No. 6, p. 243 to 247). Thus, Ga3d spectrum LG after the background correction can be determined based on a difference between the Ga3d spectrum obtained based on the actual measurement and the background. Further, As3d spectrum LA after the background correction can be determined based on a difference between the As3d spectrum obtained based on the actual measurement and the background.

When obtaining Ga3d spectrum LG, the peak of the detection intensity of the Ga element (Ga⁺) present as the Ga₂O is fixed at a position corresponding to a binding energy of 19.9 eV, and the peak position of the detection intensity of the Ga element (Ga³⁺) present as the Ga₂O₃ is fixed at a position corresponding to a binding energy of 20.7 eV. Further, the peak of the detection intensity of the Ga element (Ga—As) present as the GaAs is set at a position corresponding to a binding energy of about 19.2 to 19.7 eV so as to have a width. This is due to the following reason: when the X-ray photoelectron spectroscopy is performed onto the GaAs single crystal, charge shift may occur to cause the Ga3d spectrum to be shifted to the high energy side by about 1 eV at maximum. Moreover, since the peak of the detection intensity of the Ga—As is affected by the main layer composed of GaAs, it is difficult to fix the peak to one value and the peak position is therefore set to have a width of 0.5 eV as described above.

When obtaining As3d spectrum LA, the peak of the detection intensity of the As element (As⁵⁺) present as the As₂O₅ is fixed at a position corresponding to a binding energy of 45.57 eV, and the peak position of the detection intensity of the As element (As³⁺) present as the As₂O₃ is fixed at a position corresponding to a binding energy of 44.07 eV. Further, the peak of the detection intensity of the As element (metal As) present as the metal As is set at a position corresponding to a binding energy of about 41.62 to 42.12 eV so as to have a width, and the peak of the detection intensity of the As element (As—Ga) present as the GaAs is set at a position corresponding to a binding energy of about 40.77 to 41.27 eV so as to have a width. This is due to the following reason: when the X-ray photoelectron spectroscopy is performed onto the GaAs single crystal, charge shift may occur to cause the As3d spectrum to be shifted to the high energy side by about 1 eV at maximum. Moreover, since each peak of the metal As and the As—Ga is affected by the main layer composed of GaAs, it is difficult to fix the peak to one value and the peak position is therefore set to have a width of 0.5 eV as described above.

Next, Ga3d spectrum LG after the background correction as obtained in the manner described above is expressed by separation of Ga3d spectrum LG into the following three Gaussian functions Y1, Y2, and Y3 (hereinafter, this operation is also referred to as “peak separation”). In this way, the three spectra of the Ga element (Ga⁺) present as the Ga₂O, the Ga element (Ga³⁺) present as the Ga₂O₃, and the Ga element (Ga—As) present as the GaAs can be obtained by the peak separation in the range of binding energy of 16 to 26 eV.

$$Y 1 = a 1 * exp \{ ( - {( X - b 1 )}^{2} ) / c {1}^{2} \}$$

$$Y 2 = a 2 * exp \{ ( - {( X - b 2 )}^{2} ) / c {2}^{2} \}$$

$$Y 3 = a 3 * exp \{ ( - {( X - b 3 )}^{2} ) / c {3}^{2} \}$$

The unit of each of Gaussian functions Y1, Y2, and Y3 is dimensionless, the unit of each of X, b1, b2, b3, c1, c2, and c3 in Gaussian functions Y1, Y2, and Y3 is eV, and the unit of each of a1, a2, and a3 is dimensionless.

Gaussian functions Y1 to Y3 are determined by optimizing each of the variables (a1, a2, a3, b1, b2, b3, c1, c2, c3) such that the square ([actual measurement−ΣGi]²) of a difference from the actual measurement becomes minimum, under premise that the i-th component of the Ga3d is expressed by Gaussian function Gi=Ai*exp{(−(E−E1)²)/Wi²}. Among them, the values of binding energy at the peaks of the detection intensities of the Ga⁺, the Ga³⁺, and the Ga—As described above are substituted to b1 to b3, respectively.

That is, each of the variables (a1, a2, a3, b1, b2, b3, c1, c2, c3) is as follows. Each of a1, a2, and a3 is a real number of 0 or more.

$$b 1 = 19.9 eV$$

$$b 2 = 20.7 eV$$

$$19.2 eV \leq b 3 \leq 19.7 eV$$

$$0.2 eV \leq c 1 \leq 0.95 eV$$

$$0.2 eV \leq c 2 \leq 0.95 eV$$

$$0.2 eV \leq c 3 \leq 0.95 eV .$$

Thus, Gaussian functions Y1, Y2, and Y3 can be respectively represented as a Ga⁺ spectrum L2, a Ga³⁺ spectrum L1, and a Ga—As spectrum L3, which are obtained through the peak separation from Ga3d spectrum LG of FIG. 3A, for example.

Further, As3d spectrum LA after the background correction as obtained in the manner described above can be expressed by peak separation into the following four Gaussian functions Y4, Y5, Y6, and Y7. In this way, the four spectra of the As element (As⁵⁺) present as the As₂O₅, the As element (As³⁺) present as the As₂O₃, the As element (metal As) present as the metal As, and the As element (As—Ga) present as the GaAs can be obtained by the peak separation in the range of binding energy of 39 to 49 eV.

$$Y 4 = a 4 * exp \{ ( - {( X - b 4 )}^{2} ) / c {4}^{2} \}$$

$$Y 5 = a 5 * exp \{ ( - {( X - b 5 )}^{2} ) / c {5}^{2} \}$$

$$Y 6 = a 6 * exp \{ ( - {( X - b 6 )}^{2} ) / c {6}^{2} \}$$

$$Y 7 = a 7 * exp \{ ( - {( X - b 7 )}^{2} ) / c {7}^{2} \}$$

The unit of each of Gaussian functions Y4, Y5, Y6, and Y7 is dimensionless, the unit of each of X, b4, b5, b6, b7, c4, c5, c6, and c7 in Gaussian functions Y4, Y5, Y6, and Y7 is eV, and the unit of each of a4, a5, a6, and a7 is dimensionless.

Gaussian functions Y4 to Y7 are determined by optimizing each of the variables (a4, a5, a6, a7, b4, b5, b6, b7, c4, c5, c6, c7) such that the square ([actual measurement−ΣGi]²) of a difference from the actual measurement becomes minimum, under premise that the i-th component of the As3d is expressed by Gaussian function Gi=Ai*exp{(−(E−E1)²)/Wi²}. The values of binding energy at the peaks of the signal intensities of the As⁵⁺, the As³⁺, the metal As, and the As—Ga described above are substituted to b4 to b7, respectively.

That is, each of the variables (a4, a5, a6, a7, b4, b5, b6, b7, c4, c5, c6, c7) is as follows.

Each of a4, a5, a6, and a7 is a real number of 0 or more.

$$b 4 = 45.57 eV$$

$$b 5 = 44.07 eV$$

$$41.62 eV \leq b 6 \leq 42.12 eV$$

$$40.77 eV \leq b 7 \leq 41.27 eV$$

$$0.2 eV \leq c 4 \leq 0.95 eV$$

$$0.2 eV \leq c 5 \leq 0.95 eV$$

$$0.2 eV \leq c 6 \leq 0.95 eV$$

$$0.2 eV \leq c 7 \leq 1.2 eV .$$

Thus, Gaussian functions Y4, Y5, Y6, and Y7 can be respectively represented as an As⁵⁺ spectrum L4, an As³⁺ spectrum L5, a metal As spectrum L6, and an As—Ga spectrum L7, which are obtained through the peak separation from As3d spectrum LA of FIG. 3B, for example. Here, since the metal As is generated from the oxide film and the main layer due to a reaction of 2GaAs+As₂O₃→Ga₂O₃+4As, the metal As is detected as the intensity by the XPS.

It should be noted that in order to fix the peak positions of Gaussian functions Y1 to Y7, the following correction can be performed. First, a probability of generation of photoelectrons by X-ray, which is called photoionization efficiency (I), is variable depending on element, X-ray energy, and the like, and therefore data published in the following Web site is used as the value of f. Specifically, the photoionization efficiency (i) of the X-ray having an incident energy of 600 eV is 0.28 for the Ga3d and 0.42 for the As3d.

https://vuo.elettra.eu/services/elements/WebElements.html (it should be noted that documents on which the data is based are J. J. Yeh, Atomic Calculation of Photoionization Cross-Sections and Asymmetry Parameters, Gordon and Breach Science Publishers, Langhorne, PE (USA), 1993 and J. J. Yeh and I. Lindau, Atomic Data and Nuclear Data Tables, 32, 1-155 (1985)).

Moreover, since the intensity of the applied X-ray used in the synchrotron radiation facility is attenuated with passage of time, an attenuation ratio of Au4f photoelectron intensity is determined by measuring a gold (Au) standard sample at regular time intervals, and the dose of the applied X-ray is corrected based on the ratio.

In FIG. 3A, an area between Ga³⁺ spectrum L1 and the horizontal axis (X axis) corresponds to the number of photoelectrons emitted from the 3d orbital of the Ga³⁺ and therefore means the integrated intensity of the Ga³⁺. An area between Ga⁺ spectrum L2 and the horizontal axis (X axis) corresponds to the number of photoelectrons emitted from the 3d orbital of the Ga⁺ and therefore means the integrated intensity of the Ga⁺. An area between Ga—As spectrum L3 and the horizontal axis (X axis) corresponds to the number of photoelectrons emitted from the 3d orbital of the Ga—As, and therefore means the integrated intensity of the Ga—As.

In FIG. 3B, an area between As⁵⁺ spectrum L4 and the horizontal axis (X axis) corresponds to the number of photoelectrons emitted from the 3d orbital of the As⁵⁺ and therefore means the integrated intensity of the As⁵⁺. An area between As³⁺ spectrum L5 and the horizontal axis (X axis) corresponds to the number of photoelectrons emitted from the 3d orbital of the As³⁺ and therefore means the integrated intensity of the As³⁺. An area between metal As spectrum L6 and the horizontal axis (X axis) corresponds to the number of photoelectrons emitted from the 3d orbital of the metal As and therefore means the integrated intensity of the metal As. An area between As—Ga spectrum L7 and the horizontal axis (X axis) corresponds to the number of photoelectrons emitted from the 3d orbital of the As—Ga, and therefore means the integrated intensity of the As—Ga.

Therefore, the ratio of the sum of the integrated intensity of the As⁵⁺, the integrated intensity of the As³⁺, the integrated intensity of the As—Ga, and the integrated intensity of the metal As to the sum of the integrated intensity of the Ga⁺, the integrated intensity of the Ga³⁺, and the integrated intensity of the Ga—As can be determined as the first integrated intensity ratio based on the areas obtained from the above spectra and the horizontal axis. Further, the ratio of the sum of the integrated intensity of the As⁵⁺ and the integrated intensity of the As³⁺ to the sum of the integrated intensity of the Ga⁺ and the integrated intensity of the Ga³⁺ can be determined as the third integrated intensity ratio based on the areas obtained from the above spectra and the horizontal axis.

According to the present embodiment, each of the second integrated intensity ratio and the fifth integrated intensity ratio can be determined in the same manner as in the above-described method of calculating each of the first integrated intensity ratio and the third integrated intensity ratio, except that the XPS is performed onto the center of the main surface of the GaAs single crystal substrate under conditions of an incident energy of 600 eV and a photoelectron take-off angle of 85°. The fourth integrated intensity ratio can also be determined in the same manner as in the above-described method of calculating each of the first integrated intensity ratio and the third integrated intensity ratio, except that the XPS is performed onto the center of the main surface of the GaAs single crystal substrate under conditions of an incident energy of 600 eV and a photoelectron take-off angle of 45°.

### <Uniformity of Main Surface of GaAs Single Crystal Substrate>

The property of the GaAs single crystal substrate according to the present embodiment is preferably uniform in the plane of the main surface. That is, the GaAs single crystal substrate according to the present embodiment is preferably such that an epitaxial film having a reduced value of haze can be formed thereon regardless of an in-plane position in the main surface. As specific implementations of such a preferable GaAs single crystal substrate, the following implementations (a first implementation and a second implementation) can be exemplified.

### (First Implementation)

A GaAs single crystal substrate according to the first implementation has a diameter of 75 mm or more and less than 150 mm. The GaAs single crystal substrate preferably has a diameter of 75 mm or more and 105 mm or less. The GaAs single crystal substrate has a sixth integrated intensity ratio and a seventh integrated intensity ratio. Each of the sixth integrated intensity ratio and the seventh integrated intensity ratio is obtained by determining each of spectra of detection intensities of 3d electrons of the Ga and the As with respect to binding energy of a photoelectron emitted to the outside of the GaAs single crystal substrate based on X-ray photoelectron spectroscopy in which X-ray is applied to each of five measurement points on the main surface under conditions of an X-ray incident energy of 600 eV and a photoelectron take-off angle of 85°.

The sixth integrated intensity ratio is a ratio of a sum of an integrated intensity of the As element (As⁵⁺) present as the As₂O₅, an integrated intensity of the As element (As³⁺) present as the As₂O₃, an integrated intensity of the As element (As—Ga) present as the GaAs, and an integrated intensity of the As element (metal As) present as the metal As to a sum of an integrated intensity of the Ga element (Ga⁺) present as the Ga₂O, an integrated intensity of the Ga element (Ga³⁺) present as the Ga₂O₃, and an integrated intensity of the Ga element (Ga—As) present as the GaAs. The seventh integrated intensity ratio is a ratio of a sum of the integrated intensity of the As element (As⁵⁺) present as the As₂O₅ and the integrated intensity of the As element (As³⁺) present as the As₂O₃ to a sum of the integrated intensity of the Ga element (Ga⁺) present as the Ga₂O and the integrated intensity of the Ga element (Ga³⁺) present as the Ga₂O₃. A standard deviation and an average value of a ratio of the seventh integrated intensity ratio to the sixth integrated intensity ratio satisfy a relation of the standard deviation/the average value≤0.039. When the standard deviation and the average value of the ratio of the seventh integrated intensity ratio to the sixth integrated intensity ratio satisfy the relation of the standard deviation/the average value≤0.039, it means attainment of such a composition that the oxide film is rich in gallium without variation in the plane, and therefore, the oxide film in the main surface can be removed by wet etching without variation in the plane. The lower limit of each of the standard deviation and the average value of the ratio of the seventh integrated intensity ratio to the sixth integrated intensity ratio is 0, which is an ideal value. For example, the standard deviation and the average value of the ratio of the seventh integrated intensity ratio to the sixth integrated intensity ratio may satisfy a relation of the standard deviation/the average value≥0.026.

When the diameter is represented by D and two axes, which each pass through the center of the main surface, are each located on the main surface, and are orthogonal to each other, are defined as an X axis and a Y axis, coordinates (X, Y) of the five measurement points on the X axis and the Y axis are (0, 0), (D/4, 0), (0, D/4), (−D/4, 0), and (0, −D/4), respectively. Units of the D and each of the X and the Y in the coordinates (X, Y) are mm. Thus, in the GaAs single crystal substrate having the diameter of 75 mm or more and less than 150 mm, the oxide film can be effectively removed by wet etching to obtain the main surface having the high mirror surface property without variation in the plane, with the result that an epitaxial film having a reduced value of haze can be formed thereon.

### (Second Implementation)

Further, a GaAs single crystal substrate according to the second implementation has a diameter of 150 mm or more and 205 mm or less. The GaAs single crystal substrate has an eighth integrated intensity ratio and a ninth integrated intensity ratio. Each of the eighth integrated intensity ratio and the ninth integrated intensity ratio is obtained by determining each of spectra of detection intensities of 3d electrons of the Ga and the As with respect to binding energy of a photoelectron emitted to the outside of the GaAs single crystal substrate based on X-ray photoelectron spectroscopy in which X-ray is applied to each of five measurement points on the main surface under conditions of an X-ray incident energy of 600 eV and a photoelectron take-off angle of 85°.

The eighth integrated intensity ratio is a ratio of a sum of an integrated intensity of the As element (As⁵⁺) present as the As₂O₅, an integrated intensity of the As element (As³⁺) present as the As₂O₃, an integrated intensity of the As element (As—Ga) present as the GaAs, and an integrated intensity of the As element (metal As) present as the metal As to a sum of an integrated intensity of the Ga element (Ga⁺) present as the Ga₂O, an integrated intensity of the Ga element (Ga³⁺) present as the Ga₂O₃, and an integrated intensity of the Ga element (Ga—As) present as the GaAs. The ninth integrated intensity ratio is a ratio of a sum of the integrated intensity of the As element (As⁵⁺) present as the As₂O₅ and the integrated intensity of the As element (As³⁺) present as the As₂O₃ to a sum of the integrated intensity of the Ga element (Ga⁺) present as the Ga₂O and the integrated intensity of the Ga element (Ga³⁺) present as the Ga₂O₃. A standard deviation and an average value of a ratio of the ninth integrated intensity ratio to the eighth integrated intensity ratio satisfy a relation of the standard deviation/the average value≤0.022. When the standard deviation and the average value of the ratio of the ninth integrated intensity ratio to the eighth integrated intensity ratio satisfy the relation of the standard deviation/the average value≤0.022, it means attainment of such a composition that the oxide film is rich in gallium without variation in the plane, and therefore, the oxide film on the main surface can be removed by wet etching without variation in the plane. The lower limit of each of the standard deviation and the average value of the ratio of the ninth integrated intensity ratio to the eighth integrated intensity ratio is 0, which is an ideal value. For example, the standard deviation and the average value of the ratio of the ninth integrated intensity ratio to the eighth integrated intensity ratio may satisfy a relation of the standard deviation/the average value≥0.009.

When the diameter is represented by D and two axes, which each pass through the center of the main surface, are each located on the main surface, and are orthogonal to each other, are defined as an X axis and a Y axis, coordinates (X, Y) of the nine measurement points on the X axis and the Y axis are (0, 0), (D/4, 0), (0, D/4), (−D/4, 0), (0, −D/4), (D/2−10, 0), (0, D/2−10), (−(D/2−10), 0), and (0, −(D/2−10)) respectively. Units of the D and each of the X and the Y in the coordinates (X, Y) are mm. Thus, in the GaAs single crystal substrate having the diameter of 150 mm or more and 205 mm or less, the oxide film can be effectively removed by wet etching to obtain the main surface having the high mirror surface property without variation in the plane, with the result that an epitaxial film having a reduced value of haze can be formed thereon.

In each of the first implementation and the second implementation described above, a specific analysis method of determining each of the sixth integrated intensity ratio, the seventh integrated intensity ratio, the eighth integrated intensity ratio, and the ninth integrated intensity ratio is the same as the method described in the section <Method of Analyzing GaAs Single Crystal Substrate by X-Ray Photoelectron Spectroscopy (XPS) using Synchrotron Radiation>, and therefore the same explanation will not be described repeatedly.

### (Five Measurement Points and Nine Measurement Points)

The GaAs single crystal substrate according to the first implementation has the diameter of 75 mm or more and less than 150 mm. In this case, on the main surface of the GaAs single crystal substrate according to the first implementation, the five measurement points are set as follows. That is, in order to evaluate the effect of reducing the value of the haze of the epitaxial film due to the uniform in-plane distribution of the ratio of the seventh integrated intensity ratio to the sixth integrated intensity ratio, it is preferable to set the five measurement points such that distances therebetween become as large as possible, and measure the value of the haze generated in the epitaxial film grown at a region near each of the five measurement points. On this occasion, the value of the haze is preferably measured for a region having a diameter of 20 mm or more. Therefore, on the main surface of the GaAs single crystal substrate, five circular measurement targets each having a diameter of 20 mm are set such that distances therebetween become as large as possible. The center of each measurement target is set as the measurement point.

First, when the two axes, which each pass through the center of the main surface, are each located on the main surface, and are orthogonal to each other, are defined as the X axis and the Y axis, the coordinates (X, Y) of the first measurement point among the five measurement points on the X axis and the Y axis are set to (0, 0). It should be noted that each of the X axis and the Y axis is set such that a notch formed in the GaAs single crystal substrate is located in the third quadrant of the XY coordinate plane and a general angle of a half line passing through the notch becomes 225° with respect to a half line extending from the origin in the positive direction of the X axis.

Among the five measurement points, the second measurement point, the third measurement point, the fourth measurement point, and the fifth measurement point are disposed at equal intervals on a circumference consisting of a set of points each separated from the center of the GaAs single crystal substrate by D/4. Specifically, the coordinates (X, Y) of the second measurement point are set to (D/4, 0). The coordinates (X, Y) of the third measurement point are set to (0, D/4). The coordinates (X, Y) of the fourth measurement point are set to (−D/4, 0). The coordinates (X, Y) of the fifth measurement point are set to (0, −D/4). The D represents the diameter of the GaAs single crystal substrate, and the units of the D and each of the X and the Y in the coordinates (X, Y) are mm.

The GaAs single crystal substrate according to the second implementation has the diameter of 150 mm or more and 205 mm or less. In this case, on the main surface of the GaAs single crystal substrate according to the second implementation, four measurement points are further added in addition to the five measurement points set in the GaAs single crystal substrate according to the first implementation, and the total of nine measurement points are set as follows. That is, on the main surface of the GaAs single crystal substrate according to the second implementation, in addition to the second measurement point, the third measurement point, the fourth measurement point, and the fifth measurement point described above, four measurement targets each having a diameter of 20 mm are set so as to be located on the outer peripheral side with respect to these measurement points and so as not to overlap with the measurement targets including the second measurement point, the third measurement point, the fourth measurement point, and the fifth measurement point. The center of each of the measurement targets is set as the measurement point, and X-ray is applied to the measurement point. Specifically, the coordinates (X, Y) of the sixth measurement point of the four added measurement points are set to (0, D/2−10). The coordinates (X, Y) of the seventh measurement point are set to (D/2−10, 0). The coordinates (X, Y) of the eighth measurement point are set to (−(D/2−10), 0). The coordinates (X, Y) of the ninth measurement point are set to (0, −(D/2−10)). The D represents the diameter of the GaAs single crystal substrate, and the units of the D and each of the X and the Y in the coordinates (X, Y) are mm.

It has been known that in a large-diameter main surface having a diameter of 150 mm or more and 205 mm or less such as the main surface of the GaAs single crystal substrate according to the second implementation, the property tends to be more varied at a region on the further outer peripheral side. Therefore, in order to evaluate the effect of reducing the value of the haze of the epitaxial film due to the uniform in-plane distribution of the ratio of the ninth integrated intensity ratio to the eighth integrated intensity ratio, it is desirable to measure, in addition to the above-described five measurement points, the value of the haze generated in the epitaxial film grown at a region located on the further outer peripheral side. In order to address this, in addition to the above-described five measurement points on the main surface of the GaAs single crystal substrate, four measurement targets each having a diameter of 20 mm and measurement points serving as the respective centers of the measurement targets are set in the region on the further outer peripheral side such that distances therebetween are as large as possible.

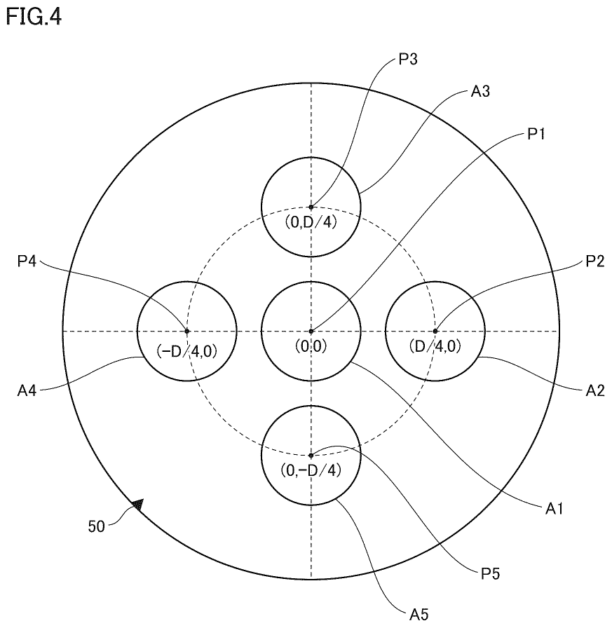

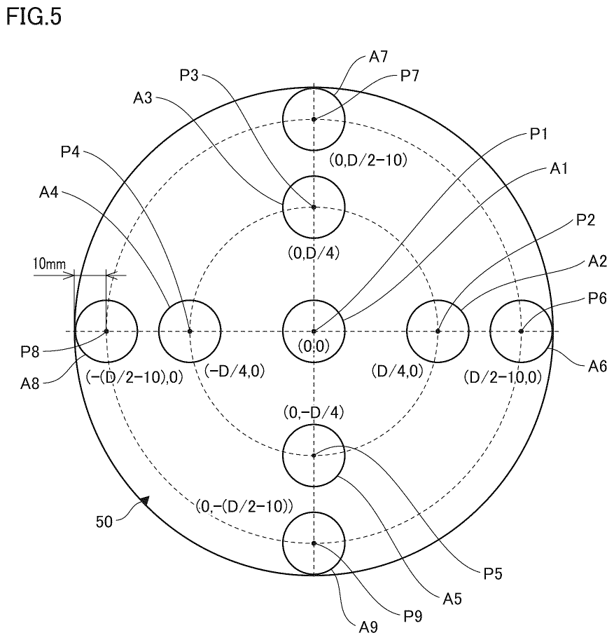

FIG. 4 is an explanatory diagram illustrating the five measurement points set in the GaAs single crystal substrate having the diameter of 75 mm or more and less than 150 mm in the present embodiment. FIG. 5 is an explanatory diagram illustrating the nine measurement points set in the GaAs single crystal substrate having the diameter of 150 mm or more and 205 mm or less in the present embodiment.

As shown in FIG. 4, in the GaAs single crystal substrate according to the first implementation, each of the X axis and the Y axis is set such that the general angle of the half line passing through notch 50 becomes 225° with respect to the half line extending from the origin in the positive direction of the X axis. Next, a first measurement point P1 is set at the origin (0, 0), which is the center of the GaAs single crystal substrate, and a measurement target A1, which is a circular region having a diameter of 20 mm and centered on first measurement point P1, is set.

Next, a second measurement point P2, a third measurement point P3, a fourth measurement point P4, and a fifth measurement point P5 are set on a circumference consisting of a set of points each separated from the center of the GaAs single crystal substrate by D/4. Further, a measurement target A2, a measurement target A3, a measurement target A4, and a measurement target A5, which are circular regions each having a diameter of 20 mm and respectively centered on second measurement point P2, third measurement point P3, fourth measurement point P4, and fifth measurement point P5, are set.

For example, when the example shown in FIG. 4 illustrates a GaAs single crystal substrate having a diameter of 75 mm, the coordinates (X, Y) (the units of X and Y are mm; the same applies to the description below) of second measurement point P2, third measurement point P3, fourth measurement point P4, and fifth measurement point P5 are set to (18.75, 0), (0, 18.75), (−18.75, 0), and (0, −18.75), respectively. Here, in the GaAs single crystal substrate having the diameter of 75 mm, measurement target A1 overlaps with measurement target A2, measurement target A3, measurement target A4, and measurement target A5 at some regions. However, such overlapping is acceptable because it is not disadvantageous from the viewpoint of evaluating the uniformity of the main surface of the GaAs single crystal substrate.

As shown in FIG. 5, in the GaAs single crystal substrate according to the second implementation, in addition to first measurement point P1 to fifth measurement point P5 set in the GaAs single crystal substrate according to the first implementation, a sixth measurement point P6, a seventh measurement point P7, an eighth measurement point P8, and a ninth measurement point P9, which are the four measurement points, are set at equal intervals on the circumference located on the outer peripheral side with respect to second measurement point P2, third measurement point P3, fourth measurement point P4, and fifth measurement point P5 and located inward by 10 mm from the outer periphery of the GaAs single crystal substrate. Further, a measurement target A6, a measurement target A7, a measurement target A8, and a measurement target A9, which are circular regions each having a diameter of 20 mm and respectively centered on sixth measurement point P6, seventh measurement point P7, eighth measurement point P8, and ninth measurement point P9, are set.

For example, when the example shown in FIG. 5 illustrates a GaAs single crystal substrate having a diameter of 150 mm, the coordinates (X, Y) of second measurement point P2, third measurement point P3, fourth measurement point P4, and fifth measurement point P5 are set to (37.5, 0), (0, 37.5), (−37.5, 0), and (0, 37.5), respectively. Further, the coordinates (X, Y) of sixth measurement point P6, seventh measurement point P7, eighth measurement point P8, and ninth measurement point P9 are set to (65, 0), (0, 65), (−65, 0), and (0, −65), respectively.

### <Epitaxial Film>

The GaAs single crystal substrate preferably has an epitaxial film disposed on the main surface. In this case, a maximum value of haze of a surface of the epitaxial film is preferably 100 ppm or less, and an average value of the haze of the surface of the epitaxial film is preferably 2.5 ppm or less. The maximum value of the haze of the surface of the epitaxial film is more preferably 20 ppm or less, and the average value of the haze of the surface of the epitaxial film is more preferably 2.0 ppm or less. The lower limit of each of the maximum value and the average value of the haze of the surface of the epitaxial film is 0, which is an ideal value.

The epitaxial film is, for example, a compound film composed of Al_{1-y-z}Ga_{y}In_{z}As, where y may be 0 or more and 1 or less, z may be 0 or more and 1 or less, and the sum of y and z may be 0 or more and 1 or less. That is, in the present embodiment, a compound film composed of Al_{1-y-z}Ga_{y}In_{z}As (0≤y≤1, 0≤z≤1, 0≤y+z≤1) can be applied as the epitaxial film formed on the main surface of the GaAs single crystal substrate. Further, the epitaxial film can be a compound film of AlₓGa₁₋ₓN (0≤x≤1) or AlₓGa₁₋ₓAs (0≤x≤1).

The epitaxial film is formed to have a thickness of, for example, 0.5 to 10 μm. When the thickness of the epitaxial film falls within the above range, the GaAs single crystal substrate can be applied in a wide range of purposes of use. More preferably, the epitaxial film has a thickness of 1 to 5 μm.

The value of the haze of the epitaxial film disposed on the main surface of the GaAs single crystal substrate can be determined by a conventionally known surface foreign matter inspection apparatus (for example, trade name: “Surfscan6420” provided by KLA-Tencor Corporation). The apparatus can perform measurement onto the entire surface of the epitaxial film (except for a region of 2 mm inward from the outer periphery of the substrate), and can measure the value of the haze (amount of scattered light (ppm)) per cm² on the surface of the epitaxial film. Based on a result of such measurement, each of the maximum value and the average value of the haze of the surface of the epitaxial film can be determined.

### [Method of Producing Gallium Arsenide Single Crystal Substrate]

A method of producing a gallium arsenide single crystal substrate (GaAs single crystal substrate) according to the present embodiment is preferably a production method of producing the GaAs single crystal substrate described above. For example, the production method includes: a step (preparation step) of preparing a gallium arsenide single crystal substrate precursor (hereinafter, also referred to as “GaAs single crystal substrate precursor”) having a surface having a circular shape; and a cleaning step of obtaining the GaAs single crystal substrate from the GaAs single crystal substrate precursor. The cleaning step includes: a step (surface polishing step) of forming the surface of the GaAs single crystal substrate precursor into a polished surface by polishing the surface; a step (first alkali cleaning step) of forming the polished surface into an alkali-cleaned surface by cleaning the polished surface with a first alkali cleaning liquid; a step (acid cleaning step) of forming the alkali-cleaned surface into an acid-cleaned surface by cleaning the alkali-cleaned surface with an acid cleaning liquid including 0.3 mass ppm or more and 0.5 mass % or less of an acid; a step (second alkali cleaning step) of forming the acid-cleaned surface into a second alkali-cleaned surface by cleaning the acid-cleaned surface by supplying a second alkali cleaning liquid to the acid-cleaned surface at a flow rate of 0.1 L/minute or more and 5 L/minute or less for 30 seconds or more and 5 minutes or less while rotating the acid-cleaned surface at a rotation speed of 1000 rpm or more in a peripheral direction; and a step (heat treatment step) of forming the second alkali-cleaned surface into the main surface by performing heat treatment onto the second alkali-cleaned surface in an inert gas atmosphere under conditions of 1.1 atmospheric pressures or more and 3 atmospheric pressures or less and 150° C. or more and 300° C. or less. The first alkali cleaning liquid includes 0.1 mass % or more and 10 mass % or less of a first base. The first base at least includes one of a quaternary ammonium hydroxide and a quaternary pyridinium hydroxide. The second alkali cleaning liquid includes 0.3 mass ppm or more and 0.5 mass % or less of a second base. The second base at least includes one of the quaternary ammonium hydroxide and the quaternary pyridinium hydroxide.

With the production method having such a feature, it is possible to obtain a GaAs single crystal substrate having a main surface with an oxide film that can be effectively removed by wet etching. The production method preferably includes a step (epitaxial film formation step) of forming an epitaxial film on the main surface. Thus, it is possible to obtain a GaAs single crystal substrate having a main surface on which an epitaxial film having a reduced value of haze is formed.

In the present specification, the term “gallium arsenide single crystal substrate precursor (GaAs single crystal substrate precursor)” refers to a GaAs single crystal substrate having a circular surface and cut out from a gallium arsenide single crystal (hereinafter, also referred to as “GaAs single crystal”) produced by a conventionally known production method such as a vertical boat method, and particularly refers to a GaAs single crystal substrate to be subjected to each step included in the cleaning step.

The present inventors have paid attention to improving a conventionally known cleaning step of obtaining the GaAs single crystal substrate, based on the knowledge obtained based on the analysis through the above-described XPS using synchrotron radiation. In particular, it has been known that the oxide film of the GaAs single crystal substrate is formed by oxidizing the surface in the acid cleaning step of removing an impurity in an alkali cleaning agent adhered to the surface of the GaAs single crystal substrate precursor after the alkali cleaning. Therefore, attention is paid to performing, after the acid cleaning step, a process to attain a composition rich in gallium (gallium oxide, hereinafter, also referred to as “Ga oxide”) in each of the oxide film and the vicinity of the interface between the oxide film and the layer composed of GaAs and included in the GaAs single crystal substrate. Specifically, progress of oxidation of the oxide film was suppressed by further performing the second alkali cleaning step, i.e., so-called spin cleaning by supplying the alkali cleaning liquid to the surface of the GaAs single crystal substrate precursor for the sake of cleaning while rotating the surface after cleaning the surface in the order of the alkali cleaning step and the acid cleaning step. Further, the surface having been through the second alkali cleaning step was subjected to heat treatment to modify the composition of the oxide film such that Ga oxide was dominant. In this way, it has been found that the composition rich in Ga oxide can be obtained in each of the oxide film and the vicinity of the interface between the oxide film and the layer composed of GaAs and included in the GaAs single crystal substrate. In the GaAs single crystal substrate having been through such a cleaning method, the oxide film having excellent wettability is formed in the main surface, with the result that the oxide film can be effectively removed by wet etching. Thus, the present inventors could obtain the GaAs single crystal substrate having the main surface having the high mirror surface property, thereby arriving at the method of producing the GaAs single crystal substrate on which an epitaxial film having a reduced value of haze can be formed.

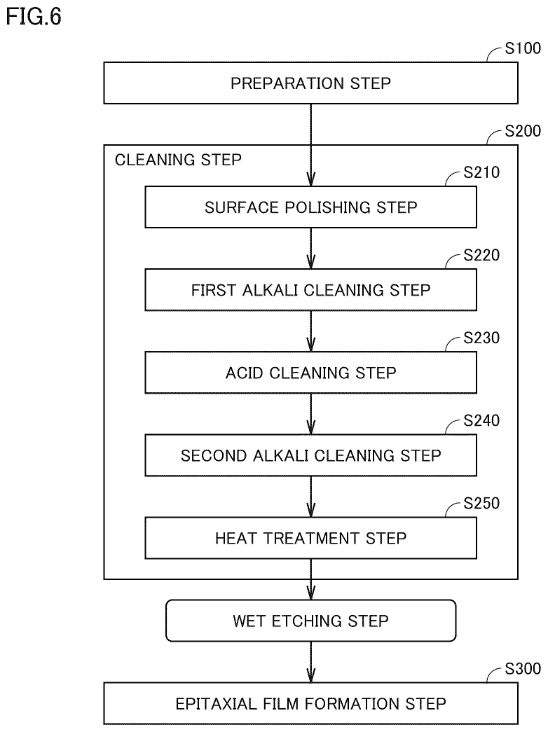

Hereinafter, each of the steps included in the method of producing the GaAs single crystal substrate according to the present embodiment will be specifically described with reference to FIG. 6. FIG. 6 is a flowchart showing the method of producing the GaAs single crystal substrate according to the present embodiment.

### <Preparation Step S100>

The method of producing the GaAs single crystal substrate includes the step (preparation step S100) of preparing the GaAs single crystal substrate precursor having the surface having the circular shape. In preparation step S100, the GaAs single crystal substrate precursor required to perform the cleaning step is prepared. Preparation step S100 can include a step of performing a conventionally known method of producing a GaAs single crystal substrate precursor. That is, preparation step S100 can include a step of producing a GaAs single crystal using a conventionally known production method such as a vertical boat method and cutting out a GaAs single crystal substrate precursor having a surface having a circular shape from the GaAs single crystal. It should be noted that when producing a GaAs single crystal substrate precursor having a (100) plane as its main surface, for example, the GaAs single crystal substrate precursor can be obtained by cutting it out from a GaAs single crystal grown in a <100> direction as a growth direction such that the (100) plane becomes the main surface. Preparation step S100 can also include a step of processing, into a desired size (for example, a disk shape having a diameter of 2 to 8 inches and a thickness of 250 to 1500 μm), the GaAs single crystal substrate precursor cut out from the GaAs single crystal. As the processing method, a conventionally known method such as slicing or chamfering can be used.

### <Cleaning Step S200>

The method of producing the GaAs single crystal substrate includes cleaning step S200 of obtaining the GaAs single crystal substrate from the GaAs single crystal substrate precursor. With this cleaning step S200, the GaAs single crystal substrate having the main surface with the oxide film that can be effectively removed by wet etching can be obtained from the GaAs single crystal substrate precursor. Cleaning step S200 includes: the step (surface polishing step S210) of forming the surface of the GaAs single crystal substrate precursor into the polished surface by polishing the surface; the step (first alkali cleaning step S220) of forming the polished surface into the alkali-cleaned surface by cleaning the polished surface with the first alkali cleaning liquid; and the step (acid cleaning step S230) of forming the alkali-cleaned surface into the acid-cleaned surface by cleaning the alkali-cleaned surface with the acid cleaning liquid including 0.3 mass ppm or more and 0.5 mass % or less of the acid; the step (second alkali cleaning step S240) of forming the acid-cleaned surface into the second alkali-cleaned surface by cleaning the acid-cleaned surface by supplying the second alkali cleaning liquid to the acid-cleaned surface at the flow rate of 0.1 L/minute or more and 5 L/minute or less for 30 seconds or more and 5 minutes or less while rotating the acid-cleaned surface at the rotation speed of 1000 rpm or more in the peripheral direction; and the step (heat treatment step S250) of forming the second alkali-cleaned surface into the main surface by performing the heat treatment onto the second alkali-cleaned surface in the inert gas atmosphere under conditions of 1.1 atmospheric pressures or more and 3 atmospheric pressures or less and 150° C. or more and 300° C. or less. Hereinafter, each of the steps included in cleaning step S200 will be described in detail.

### (Surface Polishing Step S210)

Surface polishing step S210 is the step of forming the surface of the GaAs single crystal substrate precursor into the polished surface by polishing the surface. By surface polishing step S210, the surface of the GaAs single crystal substrate precursor is formed into a mirror-finished polished surface. For example, by surface polishing step S210, the surface of the GaAs single crystal substrate precursor can be formed into a polished surface having a surface roughness of 0.3 nm or less, which is expressed by an arithmetic mean roughness Ra. As a polishing method in surface polishing step S210, various polishing methods can be used, such as conventionally known mechanical polishing and chemical mechanical polishing.

### (First Alkali Cleaning Step S220)

First alkali cleaning step S220 is the step of forming the polished surface into the alkali-cleaned surface by cleaning the polished surface with the first alkali cleaning liquid. By first alkali cleaning step S220, a foreign matter, impurity, or the like adhered to the polished surface of the GaAs single crystal substrate precursor can be removed using the first alkali cleaning liquid. The first alkali cleaning liquid is not particularly limited, but an aqueous solution including 0.1 to 10 mass % of an organic alkali compound not including a metal element that affects the electrical property is preferably used, and examples of the organic alkali compound include a quaternary ammonium hydroxide such as choline or tetramethylammonium hydroxide (TMAH), a quaternary pyridinium hydroxide, or the like.

### (Acid Cleaning Step S230)

Acid cleaning step S230 is the step of forming the alkali-cleaned surface into the acid-cleaned surface by cleaning the alkali-cleaned surface with the acid cleaning liquid including 0.3 mass ppm or more and 0.5 mass % or less of the acid. By acid cleaning step S230, an impurity included in the first alkali cleaning liquid and adhered to the alkali-cleaned surface of the GaAs single crystal substrate precursor can be removed by an oxidation reaction (etching of the alkali-cleaned surface) with the acid cleaning liquid. In particular, in acid cleaning step S230, the alkali-cleaned surface is cleaned with the acid cleaning liquid including 0.3 mass ppm or more and 0.5 mass % or less of the acid. Thus, the ratio of the Ga atoms and the As atoms in the main surface becomes appropriate and an excess of oxide film is suppressed from being generated, with the result that the oxide film can be efficiently removed by wet etching. In acid cleaning step S230, the alkali-cleaned surface is preferably cleaned with an acid cleaning liquid including 0.3 mass ppm or more and 0.1 mass % or less of the acid.

When the acid concentration of the acid in the acid cleaning liquid is less than 0.3 mass ppm, a modifying action on the alkali-cleaned surface becomes small. On the other hand, an influence of carbon dioxide (CO₂) gas dissolved in the acid cleaning liquid from an atmospheric atmosphere becomes large, thereby causing a variation in chemical composition of the acid-cleaned surface after acid cleaning step S230. When the acid concentration of the acid in the acid cleaning liquid is more than 0.5 mass %, the chemical composition of the acid-cleaned surface (and the main surface in the subsequent step) tends to be varied because deviation of the acid-cleaned surface from the stoichiometry is large due to the action of the acid. Here, the term “stoichiometry” means that when a certain compound is present, a ratio (composition) of the numbers of atoms constituting the compound is the same as in the chemical formula.

The acid included in the acid cleaning liquid is not particularly limited, but is preferably an acid component that has a high cleaning power, that does not include an element (for example, a metal element, sulfur, or the like) affecting the electrical property, and that is less likely to cause serious secondary contamination and facility deterioration in response to evaporation of the acid component together with a water component when droplets are scattered in the facility. For example, the acid included in the acid cleaning liquid preferably includes at least one inorganic acid selected from a group consisting of hydrofluoric acid (HF), hydrochloric acid (HCl), nitric acid (HNO₃), and nitrous acid (HNO₂). As the acid, an organic acid such as acetic acid, citric acid, or malic acid can also be preferably used. Further, two or more of these acids may be used in combination, for example, the hydrochloric acid and the nitric acid may be used in combination.

From the viewpoint of the cleaning property, the acid cleaning liquid more preferably includes 0.3 mass ppm to 0.3 mass % of hydrogen peroxide (H₂O₂). When the concentration of the H₂O₂ is less than 0.3 mass ppm, an influence of dissolved oxygen in the acid cleaning liquid may become large, with the result that the effect of promoting the removal of the impurity may be reduced. When the concentration of the H₂O₂ is more than 0.3 mass %, an etching rate may become too high, with the result that an etching level difference may be caused in the acid-cleaned surface.

In acid cleaning step S230, the acid cleaning liquid can be supplied to the alkali-cleaned surface while rotating the GaAs single crystal substrate precursor in the peripheral direction at 100 to 800 rpm with the surface thereof being held to be horizontal. Thus, a film of the acid cleaning liquid on the alkali-cleaned surface can formed, thereby performing efficient acid cleaning while suppressing excessive oxidation of the alkali-cleaned surface. When the rotation speed of the GaAs single crystal substrate precursor is less than 100 rpm, the cleaning efficiency may be unable to be improved, whereas when the rotation speed is more than 800 rpm, the film of the acid cleaning liquid may be unable to be formed and the effect of suppressing the oxidation may be reduced.

Further, after acid cleaning step S230, preferably immediately after acid cleaning step S230, the acid-cleaned surface of the GaAs single crystal substrate precursor is preferably cleaned using pure water. The cleaning method using pure water is not particularly limited, but the acid-cleaned surface of the GaAs single crystal substrate precursor is preferably cleaned for 5 minutes or less with pure water having a dissolved oxygen concentration (DO) of 100 ppb or less. Thus, progress of excessive oxidation of the acid-cleaned surface can be suppressed. Here, the dissolved oxygen concentration of the pure water is more preferably 50 ppb or less from the viewpoint of further suppressing the progress of excessive oxidation. A total organic carbon (TOC) of the pure water is preferably 40 ppb or less from the viewpoint of a small amount of impurity. The cleaning method using pure water can also be performed by supplying the pure water to the acid-cleaned surface while rotating the GaAs single crystal substrate precursor in the peripheral direction at 100 to 800 rpm with the main surface thereof being held to be horizontal.

### (Second Alkali Cleaning Step S240)

Second alkali cleaning step S240 is the step of forming the acid-cleaned surface into the second alkali-cleaned surface by cleaning the acid-cleaned surface by supplying the second alkali cleaning liquid to the acid-cleaned surface at the flow rate of 0.1 L/minute or more and 5 L/minute or less for 30 seconds or more and 5 minutes or less while rotating the acid-cleaned surface at the rotation speed of 1000 rpm or more in the peripheral direction. By second alkali cleaning step S240, the progress of excessive oxidation reaction of GaAs in the acid-cleaned surface can be suppressed, thereby suppressing the acid-cleaned surface from having a composition rich in As oxide. Thus, the oxide film can be efficiently modified to have a composition rich in Ga oxide in heat treatment step S250 described later.

In particular, the second alkali cleaning liquid includes 0.3 mass ppm or more and 0.5 mass % or less of the base. The base is an organic alkali compound not including a metal element that affects the electrical property. Such an organic alkali compound is not particularly limited, and examples thereof include a quaternary ammonium hydroxide such as choline or tetramethylammonium hydroxide (TMAH), a quaternary pyridinium hydroxide, and the like. Thus, the progress of excessive oxidation reaction of GaAs in the acid-cleaned surface can be suppressed. When the concentration of the base in the second alkali cleaning liquid is less than 0.3 mass ppm, the effect of suppressing the progress of the excessive oxidation in the acid-cleaned surface becomes small. On the other hand, when the concentration of the base in the second alkali cleaning liquid is more than 0.5 mass %, melting of the acid-cleaned surface may occur to result in loss of flatness of the surface. The concentration of the base in the second alkali cleaning liquid is preferably 0.3 mass ppm or more and 0.1 mass % or less.

It should be noted that examples of the first alkali cleaning liquid used in first alkali cleaning step S220 as described above include an aqueous solution including 0.1 to 10 mass % of a quaternary ammonium hydroxide such as choline or tetramethylammonium hydroxide (TMAH), a quaternary pyridinium hydroxide, or the like. Each of the first alkali cleaning liquid and the second alkali cleaning liquid may include at least one base selected from a group consisting of the quaternary ammonium hydroxide and the quaternary pyridinium hydroxide, and the first alkali cleaning liquid may include the same base as that of the second alkali cleaning liquid. Each of the first alkali cleaning liquid and the second alkali cleaning liquid may include at least one base selected from the group consisting of the quaternary ammonium hydroxide and the quaternary pyridinium hydroxide, and the first alkali cleaning liquid may include a base different from that of the second alkali cleaning liquid. That is, each of the first alkali cleaning liquid and the second alkali cleaning liquid may include at least one base selected from the group consisting of the quaternary ammonium hydroxide and the quaternary pyridinium hydroxide, and the first alkali cleaning liquid may include the same base as that of the second alkali cleaning liquid or may include a base different from that of the second alkali cleaning liquid.

In second alkali cleaning step S240, the acid-cleaned surface is preferably rotated at a rotation speed of 1500 rpm or more in the peripheral direction. The upper limit of the rotation speed for rotating the acid-cleaned surface in the peripheral direction is not particularly limited, but is preferably 2000 rpm. The flow rate of the second alkali cleaning liquid to be supplied to the acid-cleaned surface is preferably 0.5 L/minute or more and 3 L/minute or less. The time for supplying the second alkali cleaning liquid to the acid-cleaned surface is preferably 30 seconds or more and 3 minutes or less. Thus, an excessive oxidation reaction of the GaAs can be more effectively suppressed in the acid-cleaned surface.

Further, after second alkali cleaning step S240, preferably, immediately after second alkali cleaning step S240, the second alkali-cleaned surface can be cleaned with pure water for a very short time that does not adversely affect the GaAs single crystal substrate precursor. For the cleaning method using pure water, the second alkali-cleaned surface of the GaAs single crystal substrate precursor is preferably cleaned for 30 seconds or less with pure water having a dissolved oxygen concentration (DO) of 100 ppb or less. Thus, an impurity adhered to the second alkali-cleaned surface can be removed. Here, the dissolved oxygen concentration of the pure water is more preferably 50 ppb or less from the viewpoint of further suppressing the progress of the excessive oxidation. A total organic carbon (TOC) of the pure water is preferably 40 ppb or less from the viewpoint of a small amount of impurity. The cleaning method using pure water can also be performed by supplying the pure water to the second alkali-cleaned surface while rotating the GaAs single crystal substrate precursor at 100 to 800 rpm with the main surface thereof being held to be horizontal.

### (Heat Treatment Step S250)

Heat treatment step S250 is the step of forming the second alkali-cleaned surface into the main surface by performing heat treatment onto the second alkali-cleaned surface in the inert gas atmosphere under the conditions of 1.1 atmospheric pressures or more and 3 atmospheric pressures or less and 150° C. or more and 300° C. or less. By heat treatment step S250, the composition of the oxide film on the second alkali-cleaned surface can be modified such that Ga oxide is dominant. In this way, the composition rich in Ga oxide can be attained in each of the oxide film and the vicinity of the interface between the oxide film and the layer composed of GaAs and included in the GaAs single crystal substrate. Thus, in the GaAs single crystal substrate, the oxide film has excellent surface wettability, with the result that the oxide film can be effectively removed by wet etching.

In heat treatment step S250, the heat treatment is performed onto the second alkali-cleaned surface in the inert gas atmosphere under the conditions of 1.1 atmospheric pressures or more and 3 atmospheric pressures or less and 150° C. or more and 300° C. or less. The type of the inert gas is not particularly limited, but argon or nitrogen is preferable. The temperature at which the heat treatment is performed is preferably 175 to 275° C. The pressure at which the heat treatment is performed is preferably 1.5 atmospheric pressures to 2.5 atmospheric pressures. By performing the heat treatment under the conditions with the above ranges, the composition of the oxide film can be appropriately rich in gallium. When the temperature for the heat treatment is less than 150° C. or the atmospheric pressures for the heat treatment are 1.1 atmospheric pressures, the oxide film tends to be insufficiently modified. When the temperature for the heat treatment is more than 300° C. or the atmospheric pressures for the heat treatment are more than 3 atmospheric pressures, the GaAs single crystal substrate may be adversely affected by the excessive heating. The time for the heat treatment is preferably performed for 1 minute to 30 minutes.

### <Wet Etching Step>

As described above, with the method of producing the GaAs single crystal substrate according to the present embodiment, the GaAs single crystal substrate having the main surface including the oxide film having the following feature can be obtained. That is, the oxide film has a composition rich in Ga oxide in each of the oxide film and the vicinity of the interface between the oxide film and the layer composed of GaAs and included in the GaAs single crystal substrate. In such a GaAs single crystal substrate, even when a wet etching step is performed under conventionally known conditions (for example, conditions that the GaAs single crystal substrate is cleaned with sulfuric acid and hydrogen peroxide mixture (H₂SO₄:H₂O₂:H₂O=7:1:1) for 1 minute, is then subjected to running water, and is dried), the oxide film can be effectively removed because the wettability of the surface of the oxide film is excellent.

### <Epitaxial Film Formation Step S300>

The method of producing the GaAs single crystal substrate according to the present embodiment preferably includes a step (epitaxial film formation step S300) of forming an epitaxial film on the main surface. By epitaxial film formation step S300, the GaAs single crystal substrate having the main surface on which an epitaxial film having a reduced value of haze is formed can be obtained. For example, a maximum value of haze of a surface of the epitaxial film may be 100 ppm or less, and an average value of the haze of the surface may be 2.5 ppm or less, thereby attaining an improved device property.

As a method of forming the epitaxial film on the main surface of the GaAs single crystal substrate in epitaxial film formation step S300, a conventionally known method can be used. The property of the epitaxial film obtained in this step is the same as that described in the section <Epitaxial Film> above, and therefore the same explanation will not be described repeatedly. Since the GaAs single crystal substrate having the main surface on which the epitaxial film is formed has a sufficiently small value of haze, the GaAs single crystal substrate can be applied to devices such as a field effect transistor, and a microwave diode, other integrated circuits, and the like as purposes of use.

### Examples

Hereinafter, the present disclosure will be described more in detail with reference to examples, but the present disclosure is not limited thereto. GaAs single crystal substrates of samples 1 to 6 described below are examples of the present disclosure, and GaAs single crystal substrates of samples 11 to 13 are comparative examples.

### [Production of GaAs Single Crystal Substrate]

### <Sample 1>

### (Preparation Step)

A plurality of GaAs single crystal substrate precursors each having a diameter of 6 inches (150 mm) and a thickness of 675 μm were each prepared by slicing and chamfering a semi-insulating GaAs single crystal having carbon (C) atoms added therein and grown by the Vertical Bridgman (VB) method.

### (Surface Polishing Step)

A surface of each of the GaAs single crystal substrate precursors was subjected to conventionally known mechanical polishing and chemical mechanical polishing. Thus, the GaAs single crystal substrate precursor having a polished surface having an arithmetic mean roughness Ra of 0.3 nm or less as defined in JIS B0601:2001 and having an off angle of 2° with respect to the (100) plane was produced.

### (First Alkali Cleaning Step)

The polished surface of the GaAs single crystal substrate precursor was immersed in an aqueous solution (first alkali cleaning liquid) including 0.5 mass % of tetramethylammonium hydroxide, at room temperature (25° C.) for 10 minutes in accordance with the vertical batch method. Thereafter, the GaAs single crystal substrate precursor was rinsed for 3 minutes with ultrapure water (electrical resistivity (specific resistance) is 18 MΩ·cm or more, TOC (total organic carbon) is less than 10 g/liter, and the number of fine particles is less than 100 particles/liter; the same applies to the description below).

### (Acid Cleaning Step)

The alkali-cleaned surface of the GaAs single crystal substrate precursor was subjected to acid cleaning in accordance with the vertical batch method using an acid cleaning liquid. In the acid cleaning, the alkali-cleaned surface of the GaAs single crystal substrate precursor was immersed, at room temperature (25° C.) for 2 minutes, in an aqueous hydrochloric acid solution including 0.3 mass ppm of hydrochloric acid as the acid cleaning liquid. Further, the GaAs single crystal substrate precursor was rinsed for 3 minutes with the same ultrapure water as the ultrapure water used in the alkali cleaning step. Thus, the alkali-cleaned surface was formed into an acid-cleaned surface.

### (Second Alkali Cleaning Step)

The acid-cleaned surface of the GaAs single crystal substrate precursor was subjected to alkali cleaning in accordance with a spin cleaning method using a second alkali cleaning liquid. Specifically, an aqueous solution including 0.3 mass ppm of tetramethylammonium hydroxide as a base was supplied, at a flow rate of 3 L/minute for 3 minutes, to the acid-cleaned surface of the GaAs single crystal substrate precursor rotated at 1500 rpm in the peripheral direction. Thereafter, the GaAs single crystal substrate precursor was rinsed for 3 minutes with the same ultrapure water as the ultrapure water used in the acid cleaning step. Thus, the acid-cleaned surface was formed into a second alkali-cleaned surface.

### (Heat Treatment Step)

The second alkali-cleaned surface of the GaAs single crystal substrate precursor was subjected to heat treatment in an argon gas atmosphere at 3 atmospheric pressures at 300° C. for 5 minutes. Thus, the second alkali-cleaned surface was formed into a main surface having a predetermined oxide film. In this way, a required number of GaAs single crystal substrates of sample 1 were obtained. In each of the GaAs single crystal substrates, the diameter and thickness of the GaAs single crystal substrate precursor was maintained.

### (Epitaxial Film Formation Step)

Wet etching was performed under conditions that the GaAs single crystal substrate was cleaned with sulfuric acid and hydrogen peroxide water (H₂SO₄:H₂O₂:H₂O=7:1:1) for 1 minute, was subjected to running water, and was dried. Further, an Al_{0.5}Ga_{0.5}As layer having a thickness of 1 μm was grown as an epitaxial layer on the main surface of one of the GaAs single crystal substrates each having been through the wet etching (hereinafter, the GaAs single crystal substrate having the main surface on which the epitaxial layer is grown is also referred to as “epitaxial substrate”). In this way, the epitaxial substrate of sample 1 was obtained. When growing the epitaxial layer, the GaAs single crystal substrate was heated to 550° C.

### <Sample 2>

A required number of GaAs single crystal substrates of sample 2 were obtained in the same manner as in sample 1, except that: in the second alkali cleaning step, an aqueous solution including 0.1 mass % of tetramethylammonium hydroxide as the base was supplied at a flow rate of 0.5 L/minute for 30 seconds to the acid-cleaned surface of the GaAs single crystal substrate precursor rotated at 1500 rpm in the peripheral direction; and in the heat treatment step, the heat treatment was performed under an argon gas atmosphere at 1.1 atmospheric pressures, at 150° C., and for 1 minute. Further, an Al_{0.5}Ga_{0.5}As layer having a thickness of 1 μm was grown as an epitaxial layer on the main surface of one of the GaAs single crystal substrates in the same manner as in sample 1.

### <Sample 11>

A required number of GaAs single crystal substrates of sample 11 were obtained in the same manner as in sample 1 except that the second alkali cleaning step and the heat treatment step were not performed. Further, an Al_{0.5}Ga_{0.5}As layer having a thickness of 1 μm was grown as an epitaxial layer on the main surface of one of the GaAs single crystal substrates in the same manner as in sample 1.

### <Sample 12>

A required number of GaAs single crystal substrates of sample 12 were obtained in the same manner as in sample 1 except that the second alkali cleaning step was not performed. Further, an Al_{0.5}Ga_{0.5}As layer having a thickness of 1 μm was grown as an epitaxial layer on the main surface of one of the GaAs single crystal substrates in the same manner as in sample 1.

### [Sample 13]

A required number of GaAs single crystal substrates of sample 13 were obtained in the same manner as in sample 1 except that the heat treatment step was not performed. Further, an Al_{0.5}Ga_{0.5}As layer having a thickness of 1 μm was grown as an epitaxial layer on the main surface of one of the GaAs single crystal substrates in the same manner as in sample 1.

### [First Test]

### <Analysis on GaAs Single Crystal Substrate Using X-Ray Photoelectron Spectroscopy>

X-ray having an energy of 600 eV was prepared by utilizing “BL17”, which is one of beamlines only for Sumitomo Electric Industries in SAGA Light Source. The X-ray is applied to the center of the main surface of each of the GaAs single crystal substrates of samples 1 and 2 and samples 11 to 13, thereby performing an analysis using X-ray photoelectron spectroscopy. It should be noted that since each of the GaAs single crystal substrates of samples 1 and 2 and samples 11 to 13 could not be entirely placed on a sample stage, a test piece was cut out from each of the GaAs single crystal substrates of samples 1 and 2 and samples 11 to 13, and the analysis was performed onto the test piece.

Analysis conditions are as follows.
Condition 1: X-ray incident energy of 600 eV and photoelectron take-off angle of 30°
Condition 2: X-ray incident energy of 600 eV and photoelectron take-off angle of 45°
Condition 3: X-ray incident energy of 600 eV and photoelectron take-off angle of 85°
Size of the test piece under each condition: 10 mm×10 mm
Pressure around the test piece under each condition: 4×10⁻⁷ Pa
High-resolution XPS analyzer (trade name: “R3000” provided by Scienta Omicron) used under each condition
Energy resolution E/AE: 3480
Plot interval for coupling energy: 0.02 eV
Integration time and number of times of integrations at each energy value: 100 ms and 50 times.

Based on a Ga3d spectrum and an As3d spectrum obtained by the XPS analysis under each of the above conditions (conditions 1 to 3), a first integrated intensity ratio (In1) and a second integrated intensity ratio (In2) were obtained, each of which is a ratio of a sum of an integrated intensity of As⁵⁺, an integrated intensity of As³⁺, an integrated intensity of As—Ga, and an integrated intensity of metal As to a sum of an integrated intensity of Ga⁺, an integrated intensity of Ga³⁺, and an integrated intensity of Ga—As in each of samples 1 and 2 and samples 11 to 13. Further, based on the Ga3d spectrum and the As3d spectrum obtained by the analysis under each of the above conditions (conditions 1 to 3), a third integrated intensity ratio (In3), a fourth integrated intensity ratio (In4), and a fifth integrated intensity ratio (In5) were obtained, each of which is a ratio of a sum of an integrated intensity of the As⁵⁺ and an integrated intensity of the As³⁺ to a sum of an integrated intensity of the Ga⁺ and an integrated intensity of the Ga³⁺ in each of samples 1 and 2 and samples 11 to 13. A ratio (In1/In2) of the first integrated intensity ratio (In1) to the second integrated intensity ratio (In2) in each of samples 1 and 2 and samples 11 to 13 was also calculated. Results are shown in Table 1. Table 1 also shows a ratio of a sum of the integrated intensity of the As⁵⁺, the integrated intensity of the As³⁺, the integrated intensity of the As—Ga, and the integrated intensity of the metal As to a sum of the integrated intensity of Ga⁺, the integrated intensity of the Ga³⁺, and the integrated intensity of the Ga—As based on the Ga3d spectrum and the As3d spectrum obtained from the XPS analysis under condition 2. In Table 1, “Total Ga” means the sum of the integrated intensity of the Ga⁺, the integrated intensity of the Ga³⁺, and the integrated intensity of the Ga—As, and “Total As” means the sum of the integrated intensity of the As⁵⁺, the integrated intensity of the As³⁺, the integrated intensity of the As—Ga, and the integrated intensity of the metal As.

### <Maximum Value and Average Value of Haze of Surface of Epitaxial Film>

For the surface of the epitaxial film in each of the epitaxial substrates of samples 1 and 2 and samples 11 to 13, a maximum value and an average value of haze of a surface of the epitaxial film in each sample were determined by using a surface foreign matter inspection apparatus (trade name: “Surfscan 6420” provided by KLA-Tencor Corporation). Results are shown in Table 1.

Further, based on the values of the maximum value and the average value of the haze of the surface of the epitaxial film, quality of the epitaxial substrate of each of samples 1 and 2 and samples 11 to 13 was determined based on the following criteria. Results are shown in Table 1.
A: the maximum value of the haze is 20 ppm or less and the average value of the haze is 2.0 ppm or less;
B: the maximum value of the haze is more than 20 ppm and 100 ppm or less and the average value of the haze is more than 2.0 ppm and 2.5 ppm or less; and
C: at least the maximum value of the haze is more than 100 ppm or the average value of the haze is more than 2.5 ppm.

### <Wettability (Contact Angle)>

Under an environment of room temperature (20 to 25° C.) and relative humidity of 40 to 60%, 2 μL of distilled water was dropped onto the center of the main surface of each of the GaAs single crystal substrates of samples 1 and 2 and samples 11 to 13, and a contact angle of a droplet of the distilled water as formed on the main surface was measured using the θ/2 method. A contact angle meter (for example, trade name (product number): Drop Master 500 provided by Kyowa Interface Science) was used for the observation of the droplet. Results are shown in Table 1.

TABLE 1

| Sample | | 600 eV | | | In1/ | haze (ppm) | | Contact | |
|---|---|---|---|---|---|---|---|---|---|
| No. | | 30° | 45° | 85° | In2 | Max | Ave | Angle | Determination |
| 1 | Total As/ | 0.99 | 0.99 | 1.01 | 0.98 | 15 | 1.5 | 6° | A |
| | Total Ga | (In1) | | (In2) | | | | | |
| | As—O/ | 0.90 | 0.83 | 0.76 | | | | | |
| | Ga—O | (In3) | (In4) | (In5) | | | | | |
| 2 | Total As/ | 0.80 | 0.85 | 1.00 | 0.80 | 20 | 2.1 | 10° | B |
| | Total Ga | (In1) | | (In2) | | | | | |
| | As—O/ | 0.97 | 0.89 | 0.78 | | | | | |
| | Ga—O | (In3) | (In4) | (In5) | | | | | |
| 11 | Total As/ | 0.95 | 1.05 | 1.08 | 0.88 | >10000 | 845 | 45° | C |
| | Total Ga | (In1) | | (In2) | | | | | |
| | As—O/ | 1.11 | 1.04 | 1.06 | | | | | |
| | Ga—O | (In3) | (In4) | (In5) | | | | | |
| 12 | Total As/ | 0.99 | 1.04 | 1.05 | 0.94 | >10000 | 356 | 25° | C |
| | Total Ga | (In1) | | (In2) | | | | | |
| | As—O/ | 0.97 | 0.93 | 1.00 | | | | | |
| | Ga—O | (In3) | (In4) | (In5) | | | | | |
| 13 | Total As/ | 0.93 | 0.99 | 1.04 | 0.89 | >10000 | 452 | 40° | C |
| | Total Ga | (In1) | | (In2) | | | | | |
| | As—O/ | 1.15 | 1.04 | 1.20 | | | | | |
| | Ga—O | (In3) | (In4) | (In5) | | | | | |

### <Review>

According to Table 1, the quality was determined to be A or B in each of the epitaxial substrates of samples 1 and 2 each satisfying all of the relations that the second integrated intensity ratio is 0.9 or more and 1.05 or less, each of the third integrated intensity ratio and the fourth integrated intensity ratio is 1.0 or less, the fifth integrated intensity ratio is 0.8 or less, and the ratio of the first integrated intensity ratio to the second integrated intensity ratio is 0.5 or more and 1 or less. On the other hand, the quality was determined to be C in each of the epitaxial substrates of samples 11 to 13, each of which did not satisfy at least one of the above relations.

### [Second Test]

### <Production of GaAs Single Crystal Substrate>

### (Sample 3)

A GaAs single crystal substrate of sample 3 was obtained in the same manner as in sample 1 except that in the preparation step, a semi-insulating GaAs single crystal having carbon (C) atoms added therein was sliced and chamfered to prepare a GaAs single crystal substrate precursor having a diameter of 3 inches (76 mm) and a thickness of 350 μm.

### (Sample 4)

A GaAs single crystal substrate of sample 4 was obtained in the same manner as in sample 1 except that in the preparation step, a semi-insulating GaAs single crystal having carbon (C) atoms added therein was sliced and chamfered to prepare a GaAs single crystal substrate precursor having a diameter of 4 inches (100 mm) and a thickness of 350 μm.

### (Sample 5)

A GaAs single crystal substrate of sample 5 was obtained in the same manner as in sample 1 except that in the preparation step, a semi-insulating GaAs single crystal having carbon (C) atoms added therein was sliced and chamfered to prepare a GaAs single crystal substrate precursor having a diameter of 6 inches (150 mm) and a thickness of 675 μm.

### (Sample 6)

A GaAs single crystal substrate of sample 6 was obtained in the same manner as in sample 1 except that in the preparation step, a semi-insulating GaAs single crystal having carbon (C) atoms added therein was sliced and chamfered to prepare a GaAs single crystal substrate precursor having a diameter of 8 inches (200 mm) and a thickness of 675 μm.

### <Analysis on Uniformity of Main Surface of GaAs Single Crystal Substrate>

### (Samples 3 and 4)

Five test pieces cut out from each of the main surfaces of the GaAs single crystal substrates of samples 3 and 4 were analyzed in the same manner as in [Analysis on GaAs Single Crystal Substrate Using X-Ray Photoelectron Spectroscopy] in the first test. In this way, a sixth integrated intensity ratio (In6) was determined, which is a ratio of a sum of an integrated intensity of the As⁵⁺, an integrated intensity of the As³⁺ an integrated intensity of the As—Ga, and an integrated intensity of the metal As to a sum of an integrated intensity of the Ga⁺, an integrated intensity of the Ga³⁺, and an integrated intensity of the Ga—As. Further, a seventh integrated intensity ratio (In7) was obtained, which is a ratio of a sum of the integrated intensity of the As⁵⁺ and the integrated intensity of the As³⁺ to a sum of the integrated intensity of the Ga⁺ and the integrated intensity of the Ga³⁺. Further, a ratio (In7/In6) of the seventh integrated intensity ratio (In7) to the sixth integrated intensity ratio (In6) was calculated. Then, a standard deviation and an average value of In7/In6 were calculated to determine the standard deviation/the average value thereof.

Each of the five test pieces includes a first measurement point P1, a second measurement point P2, a third measurement point P3, a fourth measurement point P4, and a fifth measurement point P5 shown in FIG. 4. Further, each of the five test pieces was placed in a high-resolution XPS analyzer so as to apply X-ray to each of first measurement point P1, second measurement point P2, third measurement point P3, fourth measurement point P4, and fifth measurement point P5. Results are shown in Tables 2 and 3. Table 2 shows In7/In6 in the GaAs single crystal substrate of sample 3 and the standard deviation and average value thereof. Table 3 shows In7/In6 in the GaAs single crystal substrate of sample 4 and the standard deviation and average value thereof. As the standard deviation/the average value as shown in each of Tables 2 and 3 is smaller, the property of the GaAs single crystal substrate is more uniform in the plane of the main surface.

### (Samples 5 and 6)

Nine test pieces cut out from each of the main surfaces of the GaAs single crystal substrates of samples 5 and 6 were analyzed in the same manner as in [Analysis on GaAs Single Crystal Substrate Using X-Ray Photoelectron Spectroscopy] in the first test. In this way, an eighth integrated intensity ratio (In8) was obtained, which is a ratio of a sum of an integrated intensity of the As⁵⁺, an integrated intensity of the As³⁺ an integrated intensity of the As—Ga, and an integrated intensity of the metal As to a sum of an integrated intensity of the Ga⁺, an integrated intensity of the Ga³⁺, and an integrated intensity of the Ga—As. Further, a ninth integrated intensity ratio (In9) was obtained, which is a ratio of a sum of the integrated intensity of the As⁵⁺ and the integrated intensity of the As³⁺ to a sum of the integrated intensity of the Ga⁺ and the integrated intensity of the Ga³⁺. Further, a ratio (In9/In8) of the ninth integrated intensity ratio (In9) to the eighth integrated intensity ratio (In8) was calculated. Then, the standard deviation and the average value of In9/In8 were calculated to determine the standard deviation/the average value thereof.

Each of the nine test pieces includes a first measurement point P1, a second measurement point P2, a third measurement point P3, a fourth measurement point P4, a fifth measurement point P5, a sixth measurement point P6, a seventh measurement point P7, an eighth measurement point P8, and a ninth measurement point P9 shown in FIG. 5. Further, each of the nine test pieces was placed in a high-resolution XPS analyzer so as to apply X-ray to each of first measurement point P1, second measurement point P2, third measurement point P3, fourth measurement point P4, fifth measurement point P5, sixth measurement point P6, seventh measurement point P7, eighth measurement point P8, and ninth measurement point P9. Results are shown in Tables 4 and 5. Table 4 shows In9/In8 in the GaAs single crystal substrate of sample 5 and the standard deviation and average value thereof. Table 5 shows In9/In8 in the GaAs single crystal substrate of sample 6 and the standard deviation and average value thereof. As the standard deviation/the average value as shown in each of Tables 4 and 5 is smaller, the property of the GaAs single crystal substrate is more uniform in the plane of the main surface.

TABLE 2

| | | In7/In6 |
|---|---|---|
| | Coordinates | 600 eV |
| Measurement Point | (X, Y) | 85° |
| P1 | (0, 0) | 0.75 |
| P2 | (19, 0) | 0.77 |
| P3 | (0, 19) | 0.72 |
| P4 | (−19, 0) | 0.80 |
| P5 | (0, −19) | 0.75 |

| | |
|---|---|
| Average | 0.76 |
| Standard Deviation σ | 0.029 |
| σ/Average | 0.039 |

TABLE 3

| | | In7/In6 |
|---|---|---|
| | Coordinates | 600 eV |
| Measurement Point | (X, Y) | 85° |
| P1 | (0, 0) | 0.79 |
| P2 | (25, 0) | 0.79 |
| P3 | (0, 25) | 0.80 |
| P4 | (25, 0) | 0.75 |
| P5 | (0, 25) | 0.80 |

| | |
|---|---|
| Average | 0.79 |
| Standard Deviation σ | 0.021 |
| σ/Average | 0.026 |

TABLE 4

| | | In9/In8 |
|---|---|---|
| | Coordinates | 600 eV |
| Measurement Point | (X, Y) | 85° |
| P1 | (0, 0) | 0.79 |
| P2 | (37.5, 0) | 0.78 |
| P3 | (0, 37.5) | 0.79 |
| P4 | (−37.5, 0) | 0.78 |
| P5 | (0, −37.5) | 0.79 |
| P6 | (65, 0) | 0.79 |
| P7 | (0, 65) | 0.77 |
| P8 | (−65, 0) | 0.79 |
| P9 | (0, −65) | 0.79 |

| | |
|---|---|
| Average | 0.79 |
| Standard Deviation σ | 0.007 |
| σ/Average | 0.009 |

TABLE 5

| | | In9/In8 |
|---|---|---|
| | Coordinates | 600 eV |
| Measurement Point | (X, Y) | 85° |
| P1 | (0, 0) | 0.79 |
| P2 | (50, 0) | 0.78 |
| P3 | (0, 50) | 0.78 |
| P4 | (−50, 0) | 0.78 |
| P5 | (0, −50) | 0.78 |
| P6 | (90, 0) | 0.77 |
| P7 | (0, 90) | 0.74 |
| P8 | (−90, 0) | 0.79 |
| P9 | (0, −90) | 0.80 |

| | |
|---|---|
| Average | 0.78 |
| Standard Deviation σ | 0.017 |
| σ/Average | 0.022 |

### <Review>

According to Tables 2 and 3, in each of the GaAs single crystal substrates of samples 3 and 4, the standard deviation and the average value of the ratio (In7/In6) of the seventh integrated intensity ratio (In7) to the sixth integrated intensity ratio (In6) satisfy a relation of the standard deviation/the average value≤0.039. According to Tables 4 and 5, in each of the GaAs single crystal substrates of samples 5 and 6, the standard deviation and the average value of the ratio (In9/In8) of the ninth integrated intensity ratio (In9) to the eighth integrated intensity ratio (In8) satisfy a relation of the standard deviation/the average value≤0.022. That is, it is understood that the property of each of the GaAs single crystal substrates of samples 3 to 6 is sufficiently uniform in the plane of the main surface. Therefore, since each of the GaAs single crystal substrates of samples 3 to 6 has a high mirror surface property in its entire main surface, it is expected that an epitaxial film having a reduced value of haze can be formed thereon.

Heretofore, the embodiments and examples of the present disclosure have been illustrated, but it has been initially expected to appropriately combine configurations of the embodiments and examples.

The embodiments and examples disclosed herein are illustrative and non-restrictive in any respect. The scope of the present invention is defined by the terms of the claims, rather than the embodiments and examples described above, and is intended to include any modifications within the scope and meaning equivalent to the terms of the claims.

### REFERENCE SIGNS LIST

1 GaAs single crystal substrate; 1m main surface; 10 X-ray generation facility; 11 X-ray source; 12, 14 slit; 13 grating; 20 vacuum container; 30 electron spectrometer; 50 notch; 100 analysis system; LA As3d spectrum; LG Ga3d spectrum; L1 Ga³⁺ spectrum; L2 Ga⁺ spectrum; L3 Ga—As spectrum; L4 As⁵⁺ spectrum; L5 As³⁺ spectrum; L6 metal As spectrum; L7 As—Ga spectrum; P1 first measurement point; P2 second measurement point; P3 third measurement point; P4 fourth measurement point; P5 fifth measurement point; P6 sixth measurement point; P7 seventh measurement point; P8 eighth measurement point; P9 ninth measurement point; A1 to A9 measurement target; S100 preparation step; S200 cleaning step; S210 surface polishing step; S220 first alkali cleaning step; S230 acid cleaning step; S240 second alkali cleaning step; S250 heat treatment step; S300 epitaxial film formation step.

1. A gallium arsenide single crystal substrate comprising a main surface having a circular shape, wherein
the gallium arsenide single crystal substrate has a first integrated intensity ratio, a second integrated intensity ratio, a third integrated intensity ratio, a fourth integrated intensity ratio, and a fifth integrated intensity ratio,
each of the first integrated intensity ratio and the third integrated intensity ratio is obtained by determining each of spectra of detection intensities of 3d electrons of gallium and arsenic with respect to binding energy of a photoelectron emitted to outside of the gallium arsenide single crystal substrate based on X-ray photoelectron spectroscopy in which X-ray is applied to a center of the main surface under conditions of an X-ray incident energy of 600 eV and a photoelectron take-off angle of 30°, each of the second integrated intensity ratio and the fifth integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to the center of the main surface under conditions of an X-ray incident energy of 600 eV and a photoelectron take-off angle of 85°,
the fourth integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to the center of the main surface under conditions of an X-ray incident energy of 600 eV and a photoelectron take-off angle of 45°,
each of the first integrated intensity ratio and the second integrated intensity ratio is a ratio of a sum of an integrated intensity of an arsenic element present as diarsenic pentoxide, an integrated intensity of an arsenic element present as diarsenic trioxide, an integrated intensity of an arsenic element present as gallium arsenide, and an integrated intensity of an arsenic element present as a metal arsenic to a sum of an integrated intensity of a gallium element present as digallium monoxide, an integrated intensity of a gallium element present as digallium trioxide, and an integrated intensity of a gallium element present as the gallium arsenide,
each of the third integrated intensity ratio, the fourth integrated intensity ratio, and the fifth integrated intensity ratio is a ratio of a sum of an integrated intensity of the arsenic element present as the diarsenic pentoxide and an integrated intensity of the arsenic element present as the diarsenic trioxide to a sum of an integrated intensity of the gallium element present as the digallium monoxide and an integrated intensity of the gallium element present as the digallium trioxide,
the second integrated intensity ratio is 0.9 or more and 1.05 or less,
each of the third integrated intensity ratio and the fourth integrated intensity ratio is 1.0 or less,
the fifth integrated intensity ratio is 0.8 or less, and
a ratio of the first integrated intensity ratio to the second integrated intensity ratio is 0.5 or more and 1 or less.

2. The gallium arsenide single crystal substrate according to claim 1, wherein the second integrated intensity ratio is 0.9 or more and less than 1.04.

3. The gallium arsenide single crystal substrate according to claim 1, wherein the gallium arsenide single crystal substrate has an oxide film having a thickness of 2 nm or less in the main surface.

4. The gallium arsenide single crystal substrate according to claim 3, wherein a contact angle of the oxide film is 20° or less.

5. The gallium arsenide single crystal substrate according to claim 1, wherein the gallium arsenide single crystal substrate has a diameter of 75 mm or more and 205 mm or less.

6. The gallium arsenide single crystal substrate according to claim 1, wherein
the gallium arsenide single crystal substrate has a diameter of 75 mm or more and less than 150 mm,
the gallium arsenide single crystal substrate has a sixth integrated intensity ratio and a seventh integrated intensity ratio,
each of the sixth integrated intensity ratio and the seventh integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to each of five measurement points on the main surface under conditions of an X-ray incident energy of 600 eV and a photoelectron take-off angle of 85°,
the sixth integrated intensity ratio is a ratio of a sum of an integrated intensity of the arsenic element present as the diarsenic pentoxide, an integrated intensity of the arsenic element present as the diarsenic trioxide, an integrated intensity of the arsenic element present as the gallium arsenide, and an integrated intensity of the arsenic element present as the metal arsenic to a sum of an integrated intensity of the gallium element present as the digallium monoxide, an integrated intensity of the gallium element present as the digallium trioxide, and an integrated intensity of the gallium element present as the gallium arsenide,
the seventh integrated intensity ratio is a ratio of a sum of the integrated intensity of the arsenic element present as the diarsenic pentoxide and the integrated intensity of the arsenic element present as the diarsenic trioxide to a sum of the integrated intensity of the gallium element present as the digallium monoxide and the integrated intensity of the gallium element present as the digallium trioxide,
a standard deviation and an average value of a ratio of the seventh integrated intensity ratio to the sixth integrated intensity ratio satisfy a relation of the standard deviation/the average value≤0.039, and
when the diameter is represented by D and two axes, which each pass through the center of the main surface, are each located on the main surface, and are orthogonal to each other, are defined as an X axis and a Y axis, coordinates (X, Y) of the five measurement points on the X axis and the Y axis are (0, 0), (D/4, 0), (0, D/4), (−D/4, 0), and (0, −D/4) respectively, and units of the D and each of the X and the Y in the coordinates (X, Y) are mm.

7. The gallium arsenide single crystal substrate according to claim 1, wherein
the gallium arsenide single crystal substrate has a diameter of 150 mm or more and 205 mm or less,
the gallium arsenide single crystal substrate has an eighth integrated intensity ratio and a ninth integrated intensity ratio,
each of the eighth integrated intensity ratio and the ninth integrated intensity ratio is obtained by determining each of spectra of detection intensities of 3d electrons of the gallium and the arsenic with respect to binding energy of a photoelectron emitted to the outside of the gallium arsenide single crystal substrate based on X-ray photoelectron spectroscopy in which X-ray is applied to each of nine measurement points on the main surface under conditions of an X-ray incident energy of 600 eV and a photoelectron take-off angle of 85°,
the eighth integrated intensity ratio is a ratio of a sum of an integrated intensity of the arsenic element present as the diarsenic pentoxide, an integrated intensity of the arsenic element present as the diarsenic trioxide, an integrated intensity of the arsenic element present as the gallium arsenide, and an integrated intensity of the arsenic element present as the metal arsenic to a sum of the integrated intensity of the gallium element present as the digallium monoxide, an integrated intensity of the gallium element present as the digallium trioxide, and an integrated intensity of the gallium element present as the gallium arsenide,
the ninth integrated intensity ratio is a ratio of a sum of the integrated intensity of the arsenic element present as the diarsenic pentoxide and the integrated intensity of the arsenic element present as the diarsenic trioxide to a sum of the integrated intensity of the gallium element present as the digallium monoxide and the integrated intensity of the gallium element present as the digallium trioxide,
a standard deviation and an average value of a ratio of the ninth integrated intensity ratio to the eighth integrated intensity ratio satisfy a relation of the standard deviation/the average value≤0.022, and
when the diameter is represented by D and two axes, which each pass through the center of the main surface, are each located on the main surface, and are orthogonal to each other, are defined as an X axis and a Y axis, coordinates (X, Y) of the nine measurement points on the X axis and the Y axis are (0, 0), (D/4, 0), (0, D/4), (−D/4, 0), (0, −D/4), (D/2−10, 0), (0, D/2−10), (−(D/2−10), 0), and (0, −(D/2−10)) respectively,
and units of the D and each of the X and the Y in the coordinates (X, Y) are mm.

8. The gallium arsenide single crystal substrate according to claim 1, wherein
the gallium arsenide single crystal substrate has an epitaxial film on the main surface,
a maximum value of haze of a surface of the epitaxial film is 100 ppm or less, and
an average value of the haze of the surface of the epitaxial film is 2.5 ppm or less.

9. A method of producing a gallium arsenide single crystal substrate having a main surface having a circular shape, the method comprising:
preparing a gallium arsenide single crystal substrate precursor having a surface having a circular shape; and
obtaining the gallium arsenide single crystal substrate from the gallium arsenide single crystal substrate precursor, wherein
the obtaining includes
forming the surface of the gallium arsenide single crystal substrate precursor into a polished surface by polishing the surface,
forming the polished surface into an alkali-cleaned surface by cleaning the polished surface with a first alkali cleaning liquid,
forming the alkali-cleaned surface into an acid-cleaned surface by cleaning the alkali-cleaned surface with an acid cleaning liquid including 0.3 mass ppm or more and 0.5 mass % or less of an acid,
forming the acid-cleaned surface into a second alkali-cleaned surface by cleaning the acid-cleaned surface by supplying a second alkali cleaning liquid to the acid-cleaned surface at a flow rate of 0.1 L/minute or more and 5 L/minute or less for 30 seconds or more and 5 minutes or less while rotating the acid-cleaned surface at a rotation speed of 1000 rpm or more in a peripheral direction, and
forming the second alkali-cleaned surface into the main surface by performing heat treatment onto the second alkali-cleaned surface in an inert gas atmosphere under conditions of 1.1 atmospheric pressures or more and 3 atmospheric pressures or less and 150° C. or more and 300° C. or less,
the first alkali cleaning liquid includes 0.1 mass % or more and 10 mass % or less of a first base,
the first base at least includes one of a quaternary ammonium hydroxide and a quaternary pyridinium hydroxide,
the second alkali cleaning liquid includes 0.3 mass ppm or more and 0.5 mass % or less of a second base, and
the second base at least includes one of the quaternary ammonium hydroxide and the quaternary pyridinium hydroxide.

10. The method of producing a gallium arsenide single crystal substrate according to claim 9, comprising forming an epitaxial film on the main surface.

11. The gallium arsenide single crystal substrate according to claim 2, wherein
the gallium arsenide single crystal substrate has an oxide film having a thickness of 2 nm or less in the main surface, and
a contact angle of the oxide film is 20° or less.
